(19) United States
(12) Patent Application Publication
(10) Pub. No.: US 2026/0004422 A1
(43) Pub. Date: Jan. 1, 2026

(54) METHOD AND SYSTEM FOR DETECTING PRINTING DEFECTS IN A PHOTOLITHOGRAPHY MASK

(71) Applicant: Carl Zeiss SMT GmbH, Oberkochen (DE)

(72) Inventors: Martin van Driel, Muenchen (DE); Bjoern Froehlich, Jena (DE); Niklas Georg, Haiger (DE)

(21) Appl. No.: 19/245,854

(22) Filed: Jun. 23, 2025

(30) Foreign Application Priority Data
Jun. 27, 2024 (DE) 102024118199.0

(51) Int. Cl. G06T 7/00; G01N 21/956; G03F 1/44; G03F 7/00

(52) U.S. Cl. CPC G06T 7/0012; G01N 21/95607; G03F 7/70625; G03F 7/7065; G03F 7/70666; G03F 7/706837; G03F 7/706841; G01N 2021/95676; G03F 1/44; G06T 2207/20081; G06T 2207/30144; G06T 2207/30148

(57) ABSTRACT

A method for detecting printing defects in a photolithography mask that will print on a wafer when using the photolithography mask in a specific photolithography system to print semiconductor structures on the wafer, the method comprising: acquiring a first aerial image of the photolithography mask using a mask inspection system; generating a second aerial image of the photolithography mask by applying a machine learning model (26) to the first aerial image, wherein the machine learning model is trained to map a first aerial image acquired by a mask inspection system to a second aerial image that emulates the application of the specific photolithography system to the photolithography mask; and detecting printing defects in the photolithography mask by comparing the second aerial image to a reference image.

### CROSS-REFERENCE TO RELATED APPLICATION

This application claims benefit under 35 U.S.C. § 119 (a) of German Patent Application No. 10 2024 118 199.0, filed on Jun. 27, 2024, which is incorporated herein by reference in its entirety.

### TECHNICAL FIELD

The invention relates to methods and systems for quality control and quality assurance in photolithography masks, more specifically to a method for detecting printing defects in a photolithography mask that will print on a wafer when using the photolithography mask in a specific photolithography system to print semiconductor structures on the wafer, and to a corresponding system. The methods and systems can be utilized for quantitative metrology, process monitoring, defect detection and defect review in photolithography masks.

### BACKGROUND

Semiconductor manufacturing involves precise manipulation, e.g., etching, of materials such as silicon or oxide at very fine scales in the range of nm. Therefore, a quality management process comprising quality assurance and quality control is important for ensuring high quality standards of the manufactured wafers. Quality assurance refers to a set of activities for ensuring high-quality products by preventing any defects that may occur in the development process. Quality control refers to a system of inspecting the final quality of the product. Quality control is part of the quality assurance process.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques or inverse lithography features. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithographic masks or templates for nanoimprint photolithography with ever smaller structures or pattern elements. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

On account of the tiny structure sizes of the pattern elements of photolithographic masks or templates, it is not possible to exclude errors during mask or template production. The resulting defects can, for example, arise from degeneration of photolithography masks or particle contamination. Of the various defects occurring during semiconductor structure manufacturing, photolithography related defects make up nearly half of the number of defects. Hence, in semiconductor process control, photolithography mask inspection, review, and metrology play a crucial role to monitor systematic defects. Defects detected during quality assurance processes can be used for root cause analysis, for example, to modify or repair the photolithography mask. The defects can also serve as feedback to improve the process parameters of the manufacturing process, e.g., exposure time, focus variation, etc.

Each defect in the photolithography mask can lead to unwanted behavior of the produced wafer, or a wafer can be significantly damaged. Therefore, each defect must be found and repaired if possible and necessary. Reliable and fast defect detection methods are, therefore, important for photolithography masks.

To analyze the quality of photolithography masks mask inspection systems can be used. Mask inspection systems acquire an aerial image of a photolithography mask and detect defects in the aerial image. An aerial image indicates the intensity distribution at substrate level of a wafer, when illuminating the photolithography mask with light of specific wavelengths. The aerial image is then analyzed using defect detection methods. However, the aerial image acquired with an inspection tool usually differs from the aerial image generated in a photolithography system during the photolithography process due to various reasons, for example due to a different illumination, due to the imaging optics in the photolithography system, due to the wavelength of the illumination in the inspection tool, if the inspection tool is not actinic, etc. This is particularly important in case the photolithography mask contains sub resolution assist features or inverse lithography features, since these features are not intended to be visible on the printed wafer. Thus, to determine if a defect in a photolithography mask, actually, prints on a wafer in the photolithography system and requires repair, a separate system—the photolithography system or a mask qualification system—is required. However, using two different systems for the evaluation requires time and energy and the availability of the two systems.

Therefore, it is an aspect of the invention to detect only printing defects that will print on a wafer when using the photolithography mask in a photolithography system to print semiconductor structures on the wafer. It is an aspect of the invention to detect these printing defects at a high accuracy level. It is another aspect of the invention to detect sub-resolution assist feature related and inverse lithography feature related defects.

The aspects are achieved by the invention specified in the independent claims. Advantageous embodiments and further developments of the invention are specified in the dependent claims.

### SUMMARY

Embodiments of the invention concern methods and systems for detecting printing defects in a photolithography mask.

A first embodiment involves a method for detecting printing defects in a photolithography mask that will print on a wafer when using the photolithography mask in a specific photolithography system to print semiconductor structures on the wafer, the method comprising: acquiring a first aerial image of the photolithography mask using a mask inspection system; generating a second aerial image of the photolithography mask by applying a machine learning model to the first aerial image, wherein the machine learning model is trained to map a first aerial image acquired by a mask inspection system to a second aerial image that emulates the application of the specific photolithography system to the photolithography mask; and detecting printing defects in the photolithography mask that will print on a wafer when using the photolithography mask in the specific photolithography system to print semiconductor structures on the wafer, and non-printing defects by comparing the second aerial image to a reference image, wherein the second aerial image and the reference image are of the same design. Preferably, the reference image is predominantly defect-free.

According to another embodiment, the method for detecting printing defects in a photolithography mask, that will print on a wafer when using the photolithography mask in a specific photolithography system to print semiconductor structures on the wafer, comprises: acquiring a first aerial image and defect candidates of the photolithography mask using a mask inspection system, generating a second aerial image of the photolithography mask by applying a machine learning model to the first aerial image, wherein the machine learning model is trained to map a first aerial image acquired by a mask inspection system to a second aerial image that emulates the application of the specific photolithography system to the photolithography mask, and detecting printing defects in the photolithography mask by distinguishing, among the defect candidates, between printing defects, that will print on a wafer when using the photolithography mask in the specific photolithography system to print semiconductor structures on the wafer, and non-printing defects by comparing the second aerial image to a reference image, wherein the second aerial image and the reference image are of the same design. Preferably, the reference image is predominantly defect-free.

The term “printing defects” refers to defects in the photolithography mask that print on a wafer when using the photolithography mask in a specific photolithography system. Thus, printing defects are specific to the photolithography system. Defects are localized deviations of an integrated circuit pattern from an a priori defined norm of the integrated circuit pattern. The norm of the integrated circuit pattern can be defined using one or more corresponding reference objects or reference images, e.g., by a design of the photolithography mask, simulated datasets or acquired defect-free datasets, or using models. A maximum deviation from the norm, e.g., 10% of the critical dimension, can, for example, be used to distinguish between defects and nuisances or between relevant and irrelevant deviations.

Non-printing defects refer to deviations of an integrated circuit pattern on the photolithography mask from the norm of the integrated circuit pattern that do not print on the wafer when using the specific photolithography system. It is beneficial to distinguish printing defects from non-printing defects, since only printing defects occur on the wafer and can, thus, be relevant to the functionality of the printed wafer and should be repaired. In particular, printing defects can include optical proximity correction features or inverse lithography features that print on the wafer. The method can, thus, be used to detect sub-resolution assist feature and/or inverse lithography feature related defects.

To evaluate the quality of a photolithography mask, a mask inspection system can be used. The mask inspection system acquires an aerial image of the photolithography mask and analyzes the aerial image for potential defects, i.e., defect candidates. This aerial image does not emulate the specific photolithography process and, thus, does not simulate the printed wafer. To further examine potential defects if they, actually, print on a wafer when using a specific photolithography system, a second system is commonly used. One option is to use the specific photolithography system to print a wafer from the photolithography mask and inspect the potential defect locations on the printed wafer. Another option is to use a mask qualification system that emulates the photolithography process, e.g., illumination parameters, design parameters or imaging parameters to acquire an aerial image of the regions containing the potential defects on the photolithography mask. As the photolithography process is emulated, this aerial image simulates the printed wafer.

The invention describes a third option that does not require the use of a second system (such as a photolithography system or a mask qualification system) for quality evaluation. Instead, the aerial image of the mask inspection system is used to emulate an aerial image of the photolithography mask under photolithography process conditions using machine learning methods. The method distinguishes between printing defects and non-printing defects by comparing the emulated aerial image to a reference image. By detecting only printing defects on the photolithography mask, resources, energy, computation time, system time that is now available for other tasks are saved, as unnecessary repairs of defects are prevented. In addition, unnecessary scrap is reduced in this way, thereby saving resources and protecting the environment. This process is particularly useful for detecting defects related to optical proximity correction methods, e.g., sub-resolution assist features, or to inverse lithography features, which are part of the photolithography mask but must not print on the wafer.

The second aerial image is generated by applying a machine learning model to the first aerial image. The machine learning model is trained to map a first aerial image acquired by a mask inspection system to a second aerial image that emulates the application of the specific photolithography system to the photolithography mask. In this way, the application of a second system to detect only printing defects, e.g., of a photolithography system or a mask inspection system, is not necessary. Thus, the method can be used even if only a mask inspection system is available at a site.

Furthermore, effort and costs can be saved in this way, and unnecessary repairs of non-printing defects in photolithography masks are prevented. Therefore, resources, energy, scrap and computation time are reduced. In addition, a high level of accuracy of the second aerial image and, thus, a high level of accuracy of the detected printing defects is ensured, since machine learning models directly and automatically learn important correlations from training data without requiring hand-crafted, rule-based, usually error-prone program routines.

Machine learning is a field of artificial intelligence. Machine learning methods generally build a parametric machine learning model based on training data consisting of a large number of samples. During training, an objective function or loss function is optimized. After training, the method is able to generalize the knowledge gained from the training data to new previously unencountered samples, thereby making predictions for new data. There are many machine learning methods, e.g., linear regression, k-means, support vector machines, decision trees, random forests, neural networks or deep learning approaches.

Deep learning is a class of machine learning that uses artificial neural networks with numerous hidden layers between the input layer and the output layer. Due to this complex internal structure the networks are able to progressively extract higher-level features from the raw input data. Each level learns to transform its input data into a slightly more abstract and composite representation, thus deriving low and high level knowledge from the training data. The hidden layers can have differing sizes and tasks such as convolutional or pooling layers.

Using a trained machine learning model allows for an accurate and fast computation of the second aerial image from the first aerial image. The accuracy is determined by the selected training data. The computation time is very fast, since only a forward pass of the trained machine learning model is required during inference.

An aerial image indicates the radiation intensity distribution of a photolithography system in a wafer plane for a given photolithography mask. The aerial image is, thus, used to simulate the structures on the surface of a wafer when printing the wafer using the photolithography mask in the specific photolithography system. In this disclosure, an aerial image can also refer to images of structures on a wafer as obtained after the light-sensitive chemical process. In this case, the resist and etching behavior of the photolithography process is also simulated in the aerial image. A wafer plane refers to a plane within the resist on top of the wafer in the photolithography system.

An aerial image can refer to the aerial image of a complete photolithography mask, or it can refer to the aerial image of a section of the photolithography mask.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

An optical system refers to a system that uses light to inspect a photolithography mask or wafer or to generate an integrated circuit pattern on a wafer. Optical systems comprise, for example, mask inspection systems, mask qualification systems, photolithography systems and metrology systems.

A photolithography system refers to a system that is used to fabricate integrated circuits. To this end, during the photolithography process a photolithography mask is irradiated with light to transfer the integrated circuit pattern via the photolithography mask to a substrate by use of a light-sensitive chemical process.

A mask inspection system refers to an optical system used to detect defects in a photolithography mask. The mask inspection system acquires an aerial image of the photolithography mask and analyzes the aerial image for potential defects, i.e., defect candidates. The mask inspection system scans the complete photolithography mask for defects quickly, but usually less accurately. It does not emulate settings of a photolithography system (such as illumination parameters or imaging parameters) that will be used to print wafers from the photolithography mask.

A mask qualification system refers to a system that is used to acquire an aerial image of a portion of a photolithography mask, in particular of potential defects detected using an inspection system, in order to further examine the defect candidates. The mask qualification system simulates settings of a photolithography system, e.g., illumination settings or imaging settings. The mask qualification system scans the defect candidates more accurately but less quickly than the mask inspection system. It can, for example, be used to examine if a defect is a printing defect, to verify that a photolithography mask is defect-free or whether a repair attempt was successful.

Parameters describing the photolithography system or settings of the photolithography system comprise, for example,
illumination parameters describing the illumination setting of the photolithography system, comprising the distribution and intensities of different illumination angles, e.g., an annular illumination setting, a dipole illumination setting, a quasar illumination setting, etc.,
imaging parameters such as the numerical aperture of the photolithography system and the magnification of the photolithography system, obscurations, aberrations, apodizations or distortions,
design parameters such as parameters describing the material of the photolithography mask, e.g., layer thicknesses, refractive indices of different layers, etc.

A design of a photolithography mask refers to a representation of the photolithography mask or a section thereof. The design can, for example, comprise a computer readable file, such as a computer aided design (CAD) file or a graphic design system (GDS) file, or a technical drawing, a set of polygons representing the structures of the photolithography mask or a section thereof. A design of a photolithography mask can comprise material information, e.g., complex refractive indices of materials contained in the photolithography mask, electric permittivities, magnetic permeabilities, or derived representations. A design of a photolithography mask can comprise parameters describing dimensions of structures in the photolithography mask, e.g., the thicknesses of the layers in the multilayer of an EUV mask or the thickness of absorber layers, or the dimension of the absorber structures.

A design of a photolithography mask can comprise parameters describing the location of structures in the photolithography mask, e.g., the location of absorber structures or layers in the multilayer. A design of a photolithography mask can comprise parameters describing the shape of structures in the photolithography mask, e.g., the shape of the absorber structures such as side wall angles or corner rounding, etc. A design of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. The properties of the photolithography mask can comprise material properties, e.g., refractive indices, electric permittivities, magnetic permeabilities, or derived representations. A design of a photolithography mask can comprise descriptions of the structures within the photolithography mask, e.g., in the form of curves, contours, polygons, Splines, NURBS, Bézier curves, etc.

An aerial image being of the same design as a reference image means that the design of the photolithography mask the aerial image is generated or simulated from is identical to the design of the photolithography mask the reference image is generated or simulated from. They share the same underlying design. Therefore, the aerial image and the reference image depict the same photolithography mask structures indicated by the design. The aerial image and the reference image can deviate due to different image acquisition conditions, e.g., different photolithography masks of the same design, defects in a photolithography mask, different image acquisition systems, different illumination conditions, different points in time, different sections of the same photolithography mask, etc.

A reference image is of the same design as the aerial image it is compared to, but obtained in a different way, e.g., using a different system, a different acquisition time, a different photolithography mask, a simulation method or a different part of the aerial image that has the same design. The reference image usually is an aerial image, but other formats can be used as well, e.g., SEM images. Thus, the aerial image and the reference image rely on the same design. The reference image, therefore, essentially shows the same mask structures as the aerial image it is compared to. Essentially the same mask structures means that the mask structures of the reference image and the aerial image are identical or identical up to small deviations due to errors during photolithography mask production, e.g., line edge roughness, line shortening, edge rounding, or during the image acquisition process, e.g., noise, small biases, distortion, defocus, etc. The reference image is, preferably, predominantly defect-free, which means that less than 10%, preferably less than 5%, more preferably less than 1%, most preferably less than 0.1% of the pixels in the reference image belong to a defect.

According to an example, detecting printing defects comprises detecting potential printing defects by comparing the second aerial image to the reference image, quantifying one or more properties of each potential printing defect in the second aerial image by one or more numerical values and classifying one or more potential printing defects as printing defects by comparing the one or more numerical values to a printing defect specification. In this way, a more specific analysis of the potential printing defects can be carried out, and a defect specification based on the one or more numerical values can be used to decide if a printing defect exists or not, or to classify the potential printing defects as printing defect, non-printing defect or as a candidate that requires review, etc.

In a preferred example, the photolithography mask contains sub-resolution assist features and/or inverse lithography features. These features are added to the design of a photolithography mask to improve the printed structures on the wafer. However, they can also cause printing defects that are very hard to detect. Thus, the methods disclosed herein can be used advantageously to detect sub-resolution assist feature or inverse lithography feature related printing defects.

In an example, the machine learning model receives a design of the photolithography mask as further input. The design can help to resolve ambiguities. Thus, the accuracy of the predicted printing defects is improved.

According to an example, the reference image is obtained by applying an autoencoder machine learning model to the second aerial image. An autoencoder machine learning model is trained to reconstruct aerial images without printing defects. Thus, it can be used to generate a reference image without or only small printing defects automatically and quickly. From the difference, printing defects can be derived. No further reference images need to be acquired or generated.

Alternatively, the reference image is an aerial image of a different portion of the same photolithography mask of the same design. In this way, a reference aerial image acquired under the same conditions can be obtained quickly and easily. Thus, the accuracy of the predicted printing defects is improved.

The reference image can also be obtained from a portion of the same design in a different photolithography mask. The reference image can also be obtained from the same portion of the same mask using a different image acquisition system, e.g., a different mask qualification system.

The reference image can also be simulated from the design of the photolithography mask. For example, a machine learning model trained to modify the appearance of a design of a photolithography mask to look like an aerial image can be applied to the design of the photolithography mask. Other aerial image simulation methods for simulating an aerial image from a design can be used, e.g., finite difference time domain (FDTD) or rigorous coupled wave analysis (RCWA) or the thin element approximation (TEA), or a not quite rigorous (NQR) method described below, or machine learning models that are trained to simulate the physical process of generating an aerial image from a design.

The reference image does not necessarily have to be an aerial image. Other formats can be used as well, e.g., a design file or some other model of a photolithography mask or a scanning electron microscopy (SEM) image, etc.

According to an example, the first aerial image comprises a stack of aerial images acquired of the same portion of the photolithography mask using different focus levels in the mask inspection system. By using a stack of aerial images of different focus levels, more information is provided as input to the machine learning model. Mask structures at different depths or with different heights can be viewed in focus using a stack of aerial images at different focus levels. Thus, the accuracy of the detected printing defects is improved in this way.

According to an embodiment of the invention, a computer implemented method for training a machine learning model according to any of the examples or aspects of the first embodiment of the invention described above is disclosed.

According to a second embodiment of the invention, a method for detecting printing defects in a photolithography mask that will print on a wafer when using the photolithography mask in a specific photolithography system to print semiconductor structures on the wafer, comprises: acquiring an aerial image of the photolithography mask using a mask inspection system; detecting printing defects in the photolithography mask by applying a machine learning model to the acquired aerial image and a reference image, wherein the acquired aerial image and the reference image are of the same design, and wherein the machine learning model is trained to detect printing defects in the photolithography mask, that will print on a wafer when using the photolithography mask in the specific photolithography system to print semiconductor structures on the wafer, using the acquired aerial image and the reference image. Preferably, the reference image is predominantly defect-free. The machine learning model can be trained to distinguish between printing defects and non-printing defects.

In an example, the method can comprise acquiring an aerial image and defect candidates of the photolithography mask using a mask inspection system; detecting printing defects in the photolithography mask by applying a machine learning model to the acquired aerial image and a reference image, wherein the acquired aerial image and the reference image are of the same design, and wherein the machine learning model is trained to distinguish, among the defect candidates, between printing defects, that will print on a wafer when using the photolithography mask in the specific photolithography system to print semiconductor structures on the wafer, and non-printing defects using the acquired aerial image and the reference image. Preferably, the reference image is predominantly defect-free.

Instead of using a second system to further analyze the aerial image acquired using the mask inspection system for printing defects, i.e., for defects that actually print on a wafer when using the photolithography mask in the specific photolithography system, machine learning methods are used. The machine learning model is trained to directly predict printing defects that will be generated on a wafer by the specific photolithography system in the aerial image acquired by the mask inspection system. To this end, the machine learning model can be trained using (acquired or simulated) aerial images of a mask inspection system and corresponding (acquired or simulated) aerial images simulating the application of the specific photolithography system to the photolithography mask together with corresponding printing defect detections as training data. By directly predicting printing defects from the acquired aerial image of the inspection system resources, time, scrap and energy can be saved. Furthermore, no additional system needs to be available for distinguishing printing defects from non-printing defects.

In addition, a high level of accuracy of the detected printing defects is ensured, since machine learning models directly and automatically learn important correlations from training data without requiring hand-crafted, rule-based, usually error-prone program routines. Thus, the use of a machine learning model increases the accuracy of the method.

In a preferred example, the photolithography mask contains sub-resolution assist features and/or inverse lithography features. These features are added to the design of a photolithography mask to improve the printed structures on the wafer. However, they can also cause printing defects that are very hard to detect. Thus, the methods disclosed herein can be used advantageously to detect sub-resolution assist feature or inverse lithography feature related printing defects.

According to an example, the machine learning model further assigns one or more numerical values to each printing defect detection that quantify one or more properties of the detected printing defect. In this way, numerical values can be directly assigned to the detected printing defects by the machine learning model. Due to the direct assignment by the machine learning model, the accuracy of the numerical values is increased as no further computation steps are carried out outside the machine learning model to quantify defect properties. The machine learning model is, thus, trained end-to-end and learns by itself which features are important to assign the one or more numerical values. Furthermore, the computation time is reduced as no further steps need to be carried out to quantify the defect properties.

The one or more numerical values can quantify different properties, e.g., a deviation of the mask structures of the detected printing defect from corresponding mask structures in the reference image. The deviation can, for example, include a deviation in a dimension, in a size, in an area, in a length, in a measurement characterizing line roughness, line shortening, edge rounding, noise, etc. In particular, the one or more numerical values can quantify a deviation of a critical dimension of the mask structures of the detected printing defect from the critical dimension of corresponding mask structures in the reference image. The one or more numerical values can also quantify one or more dimensions or a size of the detected printing defect. The one or more numerical values can also quantify a functionality of the wafer when printing the detected printing defect on the wafer.

In an example, the machine learning model receives a design of the photolithography mask as further input. The design can help to resolve ambiguities. Thus, the accuracy of the predicted printing defects is improved.

According to an example, the acquired aerial image comprises a stack of aerial images acquired of the same portion of the photolithography mask using different focus levels in the mask inspection system. By using a stack of aerial images of different focus levels, more information is provided as input to the machine learning model. Mask structures at different depths or with different heights can be viewed in focus using a stack of aerial images at different focus levels. Thus, the accuracy of the detected printing defects is improved in this way.

The machine learning model for detecting printing defects according to the second embodiment of the invention can be trained using a method according to the following third embodiment of the invention.

According to a third embodiment of the invention, a computer implemented method for training a machine learning model to detect printing defects in a photolithography mask that will print on a wafer when using the photolithography mask in a specific photolithography system to print semiconductor structures on the wafer, wherein the machine learning model maps an aerial image of the photolithography mask, acquired by a mask inspection system, and a reference image to printing defect detections, wherein the aerial image and the reference image are of the same design, comprises: providing design pairs containing designs and reference designs of photolithography masks, wherein the reference designs contain the same mask structures as the designs and are predominantly defect-free, and wherein at least some designs contain one or more defects; generating first aerial image pairs containing first aerial images and first reference aerial images by emulating the application of a mask inspection system to photolithography masks represented by the design pairs; generating corresponding second aerial image pairs containing second aerial images and second reference aerial images by emulating the application of the photolithography system to photolithography masks represented by the design pairs; generating corresponding printing defect detections by comparing the second aerial image to the second reference aerial image of each second aerial image pair; training the machine learning model to detect printing defects in a photolithography mask using training data comprising the generated first aerial image pairs and the corresponding generated printing defect detections.

This method can be used to train a machine learning model that directly predicts printing defects, that will occur during printing of a wafer using a specific photolithography system, from an aerial image acquired by a mask inspection system.

To this end, training data is generated that emulates the application of the specific photolithography system to the photolithography mask to obtain printing defect detections that can be directly associated with the aerial image of the mask inspection system. To this end, first aerial image pairs and second aerial image pairs are simulated. The first aerial image pairs emulate the application of a mask inspection system to the photolithography mask, whereas the second aerial image pairs emulate the application of a photolithography system to the photolithography mask. Both, the first aerial image pairs and the second aerial image pairs, are emulated using design pairs. Each design pair contains a design that can contain one more defects and a reference design. Preferably, the reference design is predominantly defect-free. Using the design pairs the first and second aerial image pairs can be obtained using an aerial image simulation method. By comparing second aerial images to corresponding second aerial reference images, printing defects can be detected. Then first aerial images and detected printing defects can be used as training data for the machine learning model for printing defect detection.

Instead of or in addition to simulated training data, first aerial image pairs can be acquired by using photolithography masks in mask inspection systems, and second aerial image pairs can be acquired using photolithography masks in mask qualification systems that emulate the application of the specific photolithography system to the photolithography masks. In this way, acquired aerial images can be used to supplement the training data, thereby increasing the accuracy of the predicted printing defects by the machine learning model. Instead of second aerial image pairs, other image formats can be used, e.g., SEM images.

According to an example, the method further comprises, for each printing defect detection, generating one or more numerical values quantifying one or more properties of the printing defect detection and adding the one or more numerical values to the training data, wherein the machine learning model is trained to quantify one or more properties of the printing defect detections by assigning one or more numerical values to the printing defect detections. In this way, the machine learning model is trained end-to-end to directly quantify properties of the printing defect detections by assigning one or more numerical values. Further computation steps for quantifying properties of the printing defect detections are not required anymore, thereby saving computation time, resources and energy, and increasing the accuracy of the quantified properties, since the machine learning model directly learns the best features to assign the numerical values from training data.

According to an example, each first aerial image and each first reference image comprises a stack of aerial images for different focus levels of the mask inspection system. By using stacks of aerial images of different focus levels, more information is provided as training data to the machine learning model. Mask structures at different depths or with different heights can be viewed in focus using a stack of aerial images at different focus levels. Thus, the accuracy of the printing defect detections is improved. A corresponding second aerial image and second reference aerial image can be generated using the best focus in the photolithography system. Alternatively, a corresponding second aerial image and second reference aerial image can also comprise a stack of aerial images for different focus levels of the photolithography system. The second aerial image pair with the best focus can be selected from the stack to derive printing defect detections and, optionally, numerical values quantifying properties of the printing defect detections. Alternatively, two or more aerial images and aerial reference images of the focus stack can be used to derive printing defect detections and, optionally, numerical values for quantifying properties of the printing defect detections. For example, the union or intersection of the printing defects derived from the two or more aerial images and aerial reference images can be used as printing defects, etc.

To generate first aerial image pairs and/or second aerial image pairs, an aerial image simulation method can be used. An aerial image simulation method simulates the generation of an aerial image of a photolithography mask from a design of the photolithography mask. To this end, methods such as rigorous coupled wave analysis (RCWA), finite difference time domain (FDTD) or Kirchhoff's thin element approximation (TEA) can be used. However, RCWA and FDTD require high computation times, whereas TEA is not sufficiently accurate in case of very small structures on the photolithography mask. Therefore, fast and accurate aerial image simulation methods are of interest.

The aerial image simulation method can, for example, use physics-based models, e.g., physics-based models of the photolithography mask and/or of the propagation of electromagnetic waves through the photolithography mask. The aerial image simulation method can also use non-physics-based models, e.g., machine learning models that are trained using training data. The aerial image simulation method can also use a combination of a physics-based model and a non-physis-based model such as a machine learning model.

In a preferred example, the aerial image simulation method comprises a physics-based model and a machine learning model for generating an aerial image from a design. The machine learning model can be applied subsequently to the physics-based model. In this way, the machine learning model can increase the accuracy of the output of the physics-based model. At the same time, it allows for using less complex physics-based models, since the result is processed further by the machine learning model.

In an example, the aerial image simulation method comprises a machine learning model that maps a design to an aerial image. Since machine learning models directly learn important correlations from training data, the aerial image simulation method is highly accurate. In addition, the computation time is low as only a single forward pass is required at inference time.

According to an example, at least one aerial image, in particular a first aerial image, a first reference aerial image, a second aerial image or a second reference aerial image, is generated from a design of the photolithography mask by emulating the application of an optical system, e.g., of the mask inspection system or the specific photolithography system, to the photolithography mask using the following steps: a) approximately simulating the propagation of incident electromagnetic waves within a first section of the photolithography mask; b) simulating the propagation of the simulated electromagnetic waves from step a) within a second section of the photolithography mask analytically or numerically; c) simulating a representation of an electromagnetic near field of the photolithography mask by propagating the simulated electromagnetic waves from step b) to a near field plane; and d) generating an aerial image of the photolithography mask by applying a simulation of an imaging process of the optical system to the representation of the electromagnetic near field. For generating a first aerial image or first reference aerial image, the optical system that is simulated is the inspection system. For generating a second aerial image or a second reference aerial image, the optical system that is simulated is the specific photolithography system.

The electromagnetic near field is computed in different ways within the first section of the photolithography mask and within the second section of the photolithography mask. Within the first section several assumptions described below can be made in the photolithography setting, which allow for a simplified and fast computation of the propagation of the electromagnetic waves within the first section. The propagation of the electromagnetic waves within the first section is computed by use of a wave propagation method, which takes into account the inhomogeneity of the medium within the first section of the photolithography mask. Within the second section, the propagation of the electromagnetic waves is computed analytically or numerically. In this way, a highly accurate approximation of the propagation of the electromagnetic waves within the photolithography mask is obtained, requiring computation times several magnitudes below rigorous simulation methods. Thus, the simulation of electromagnetic near fields and aerial images within industry applications becomes feasible.

A design of a photolithograph mask preferably describes the photolithography mask at least partially in a dimension orthogonal to a base plane of the photolithography mask. The design of the photolithography mask can comprise one or more different sections of the photolithography mask or parts thereof, for example, a first section and/or a second section. The one or more different sections can be arranged at different depths with respect to the normal of the surface of the photolithography mask.

The first section of the photolithography mask comprises multiple structures. These structures can be arranged in a design pattern or model that determines the patterns imprinted on the wafer during the printing process. The design pattern or model can comprise structures and non-structures, in particular absorber structures and non-absorber structures. The second section of the photolithography mask can contain a mask carrier that can comprise one or multiple layers of one or more materials. The structures and the non-structures can be deposited on the mask carrier. The mask carrier can comprise a substrate layer. The second section can be configured to transmit the incident electromagnetic waves (for transmission-based photolithography masks) or it can be configured to reflect the incident electromagnetic waves (for reflection-based photolithography masks). The first section can be directly adjacent to the second section of the photolithography mask. Thus, the first section and the second section can have a common boundary, e.g., a boundary plane. The mask carrier in the photolithography mask can be delimited by the boundary plane and a base plane. The boundary plane can be a surface plane of the mask carrier. The base plane is preferably parallel to the boundary plane. The base plane can delimit the second section from the outside. It can form an interface between the mask carrier and the outside of the photolithography mask through which the electromagnetic waves propagate. The structures in the first section of the photolithography mask can be delimited by the boundary plane and a structure plane. The structure plane can delimit the first section of the photolithography mask from the outside. The structure plane can contain the portion of the surface of the structures, which is facing away from the boundary plane. Preferably, the structure plane is parallel to the boundary plane. The first section of the photolithography mask can extend between the structure plane and the boundary plane and can be delimited by these planes. The second section of the photolithography mask can extend between the boundary plane and the base plane. It can be delimited by the boundary plane and the base plane. The second section can contain a stack of homogeneous parallel layers. Homogeneous means that the material properties do not change within a layer. Other constructions of photolithography masks containing a first section and a second section can also be used.

An electromagnetic near field indicates the distribution of the electromagnetic waves in a near field plane. The near field plane can be located next to a structure plane of the photolithography mask that delimits the first section of the photolithography mask from the outside. Preferably, the near field plane is parallel to the structure plane of the photolithography mask. The near field plane can be located anywhere between the structure plane and a wafer plane, for example, the near field plane can be located at a distance between 0 and 1000 nm from the structure plane, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane and the structure plane are identical. The near field plane could, in principle, also lie within the first section, within the second section, on the structure plane, on the base plane, or outside of the photolithography mask at the side of the base plane of the photolithography mask, for example in case the electromagnetic waves are re-propagated back into the photolithography mask after propagation through the first section.

A representation of an electromagnetic (near) field can refer to the (complex) electric field E or the (complex) scattered electric field E_{sc}=E−E, where E_{inc} denotes the incident electric field. A complex electromagnetic field can be represented for example, in terms of the real and imaginary part, or the amplitude and phase, etc. A representation of an electromagnetic field can refer to the (complex) magnetic field H or the (complex) scattered magnetic field H_{sc}=H−H_{inc}, where H_{inc} denotes the incident magnetic field. A representation of an electromagnetic field can comprise measurements derived from the electromagnetic field, e.g., diffraction orders, the spectrum, the far field or the intensity field, etc. A representation of an electromagnetic field within the photolithography mask can refer to the electromagnetic field within the photolithography mask, to a section of the electromagnetic field within the photolithography mask, to an electromagnetic field next to the photolithography mask, e.g., a near field, etc. A representation of an electromagnetic field can comprise representations of the electromagnetic field for different spatial directions. For example, a representation of an electromagnetic field can comprise a 2D or 3D image containing one, two or more channels, such that the 2D or 3D image comprises a representation of the electromagnetic field in each spatial direction, e.g., the complex electric field in x and y or in x, y and z directions yielding a 2D or 3D image with four or six channels.

According to a first example, the propagation of the incident electromagnetic waves within the first section of the photolithography mask in step a) is approximately simulated using a Helmholtz equation. In this way, the approximation is simplified and, thus, the complexity and the computation time reduced.

According to an aspect of the first example, the Helmholtz equation is approximated using a forward Helmholtz equation. In this way, the approximation is simplified and, thus, the complexity and the computation time reduced.

The forward Helmholtz equation can be solved using a beam propagation method. In this way, the approximation is simplified and, thus, the complexity and the computation time reduced.

In a preferred embodiment, the forward Helmholtz equation is solved using a wave propagation method that approximately describes the propagation of electromagnetic waves through an inhomogeneous medium. By using the wave propagation method, the forward Helmholtz equation is solved quickly, thereby reducing the computation time of the method. Furthermore, by taking into account the inhomogeneity of the first section of the photolithography mask, e.g., due to different materials in absorber structures and non-absorber structures, the wave propagation is simulated with high accuracy. According to a second example, the propagation of the incident electromagnetic waves within the first section of the photolithography mask in step a) is approximately simulated using a machine learning model. By using a machine learning model, the computation time can be strongly reduced, as after training a single and fast forward pass is sufficient to compute the propagation of the incident electromagnetic waves.

The trained machine learning model according to the third embodiment can be used in any of the methods for printing defect detection according to the second embodiment of the invention.

A non-transitory computer-readable medium according to an embodiment of the invention comprises a stored computer program executable by a computing device, comprising code for executing a method according to the third embodiment of the invention.

A computer program product according to an embodiment of the invention comprises instructions which, when the program is executed by a computer, cause the computer to carry out a method according to the third embodiment of the invention.

An inspection system for detecting printing defects in a photolithography mask according to an embodiment of the invention comprises a mask inspection system for acquiring an aerial image of the photolithography mask and a data analysis device comprising at least one memory and at least one processor configured to perform the steps of a computer implemented method according to the first or second embodiment of the invention.

The invention described by embodiments, examples and aspects is not limited to the embodiments, examples and aspects, but can be implemented by those skilled in the art by various combinations or modifications thereof.

### BRIEF DESCRIPTION OF DRAWINGS

FIG. 1 illustrates an exemplary transmission-based photolithography system, e.g., a deep ultraviolet (DUV) photolithography system;

FIG. 2 illustrates an exemplary reflection-based photolithography system, e.g., an extreme ultra-violet light (EUV) photolithography system;

FIG. 3 shows a flowchart of a first embodiment of a method for detecting printing defects in a photolithography mask;

FIG. 4 illustrates a first embodiment of the method for detecting printing defects in a photolithography mask;

FIGS. 5A-5D show printing defects caused by sub-resolution assist features or inverse lithography features;

FIG. 6 illustrates the use of a focus stack of aerial images as input to the machine learning model;

FIG. 7 shows a flowchart of a second embodiment of a method for detecting printing defects in a photolithography mask;

FIG. 8 illustrates a second embodiment of the method for detecting printing defects in a photolithography mask;

FIG. 9 illustrates the use of a focus stack of aerial images as input to the machine learning model;

FIG. 10 illustrates a computer implemented method for training a machine learning model to detect printing defects in a photolithography mask;

FIG. 11A shows a flowchart of a not quite rigorous method for simulating an aerial image of a photolithography mask;

FIG. 11B illustrates the propagation of incoming electromagnetic waves through a transmission-based photolithography mask;

FIG. 11C shows a flowchart of the not quite rigorous method for simulating an aerial image of a transmission-based photolithography mask;

FIG. 11D illustrates the propagation of incoming electromagnetic waves through a reflection-based photolithography mask;

FIG. 11E shows a flowchart of the not quite rigorous method for simulating an aerial image of a reflection-based photolithography mask;

FIG. 11F shows a flowchart of an example of the not quite rigorous method for simulating an aerial image of a photolithography mask including an additional characteristic function step;

FIG. 11G illustrates the dependency of the phase shift vector a on the angle $ of the incoming electromagnetic waves;

FIG. 11H illustrates the steps of the not quite rigorous method for simulating an aerial image of a photolithography mask according to an example;

FIG. 12 illustrates a mask inspection system for evaluating the quality of a photolithography mask according to a fourth embodiment of the invention.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

The methods and systems herein can be used with a variety of photolithography systems, e.g., transmission-based photolithography systems 10 or reflection-based photolithography systems 10′.

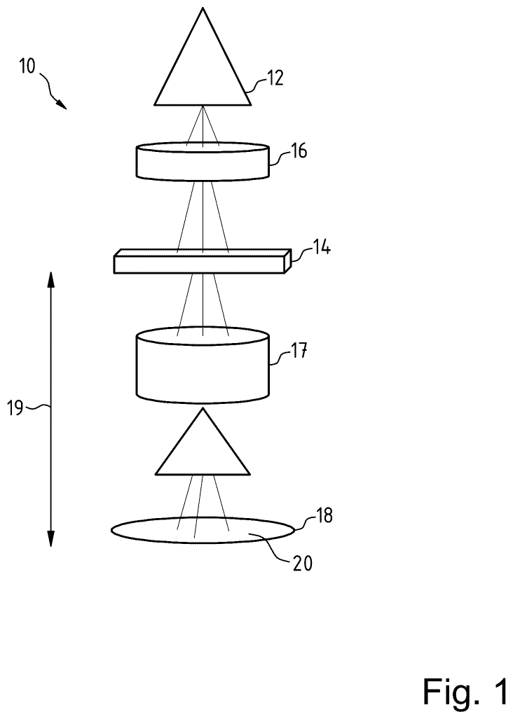

FIG. 1 illustrates an exemplary transmission-based photolithography system 10, e.g., a DUV photolithography system. Major components are a radiation source 12, which may be a deep-ultraviolet (DUV) excimer laser source, imaging optics which, for example, define the partial coherence and which may include optics that shape radiation from the radiation source 12, a photolithography mask 14, illumination optics 16 that illuminate the photolithography mask 14 and projection optics 17 that project an image of the photolithography mask design onto a wafer plane 18 of a wafer 20. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate and the last element of the projection optics 17, and Gmax is the largest angle of the beam exiting from the projection optics 17 that can still impinge on the wafer plane 18.

In the present document, the terms “radiation” or “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 3-100 nm).

Illumination optics 16 may include optical components for shaping, adjusting and/or projecting radiation from the radiation source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

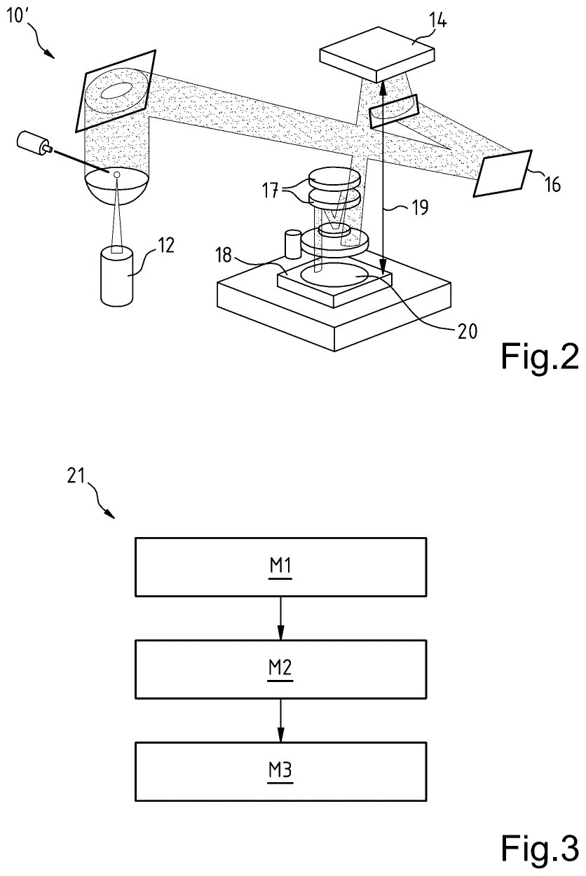

FIG. 2 illustrates an exemplary reflection-based photolithography system 10′, e.g., an extreme ultraviolet light (EUV) lithography system. Major components are a radiation source 12, which may be a laser plasma light source, illumination optics 16 which, for example, define the partial coherence and which may include optics that shape radiation from the radiation source 12, a photolithography mask 14, and projection optics 17 that project an image of the photolithography mask design onto a wafer plane 18. An adjustable filter or aperture at the pupil plane of the projection optics 17 may restrict the range of beam angles that impinge on the wafer plane 18 of a wafer 20, where the largest possible angle defines the numerical aperture of the projection optics NA=n sin(Gmax), wherein n is the refractive index of the media between the substrate and the last element of the projection optics 17, and Gmax is the largest angle of the beam exiting from the projection optics 17 that can still impinge on the wafer plane 18.

In order to detect only printing defects that print on a wafer when the photolithography mask is used in a photolithography system, usually a mask inspection system is used to detect defects in the photolithography mask, followed by the application of a second system, e.g., a photolithography system or a mask qualification system, to discriminate between printing and non-printing defects. However, using two systems requires time, resources, energy and is sometimes even not possible in case the second system is not available, e.g., if the second system is located at the customer's site. Therefore, the invention proposes to emulate the second system by use of machine learning techniques.

FIG. 3 shows a flowchart of a first embodiment of a method 21 for detecting printing defects in a photolithography mask 14 that will print on a wafer 20 when using the photolithography mask 14 in a specific photolithography system 10, 10′ to print semiconductor structures on the wafer 20, the method comprising: acquiring a first aerial image of the photolithography mask using a mask inspection system in a step M1; generating a second aerial image of the photolithography mask 14 by applying a machine learning model to the first aerial image, wherein the machine learning model is trained to map a first aerial image acquired by a mask inspection system to a second aerial image that emulates the application of the specific photolithography system 10, 10′ to the photolithography mask 14 in a step M2; and detecting printing defects 34 in the photolithography mask 14 that will print on a wafer 20 when using the photolithography mask 14 in the specific photolithography system 10, 10′ to print semiconductor structures on the wafer 20 by comparing the second aerial image 30 to a reference image 32, wherein the second aerial image 30 and the reference image 32 are of the same design in a step M3.

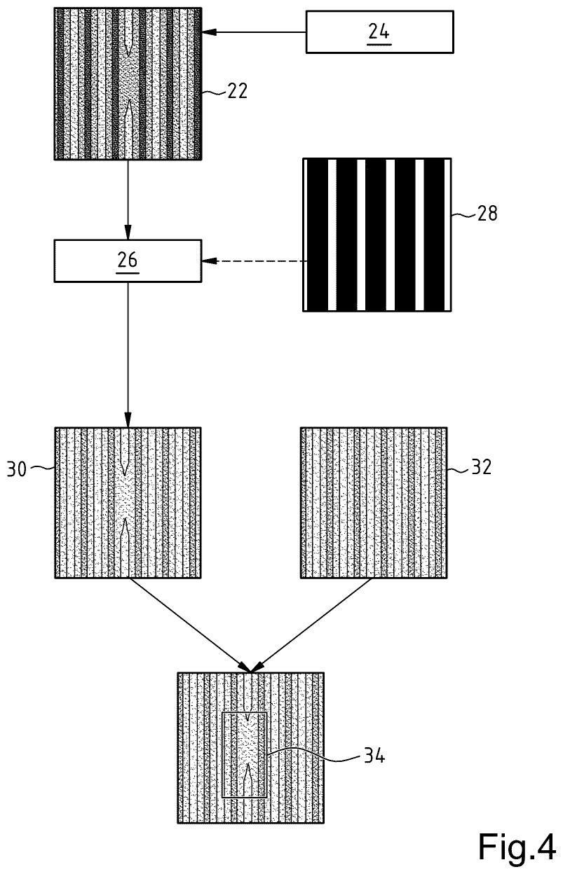

FIG. 4 illustrates the first embodiment of the method for detecting printing defects 34 in a photolithography mask 14 that will print on a wafer 20 when using the photolithography mask 14 in a specific photolithography system 10, 10′ to print semiconductor structures on the wafer 20. A first aerial image 22 of the photolithography mask 14 is acquired using a mask inspection system 24. Then a second aerial image 30 of the photolithography mask 14 is generated by applying a machine learning model 26 to the first aerial image 22. The machine learning model 26 is trained to map a first aerial image 22 acquired by a mask inspection system 24 to a second aerial image 30 that emulates the application of the specific photolithography system 10, 10′ to the photolithography mask 14. Printing defects 34 in the photolithography mask 14 are detected by comparing the second aerial image 30 to a reference image 32, wherein the reference image 32 essentially contains the same mask structures as the second aerial image 30. Preferably, the reference image 32 is predominantly defect-free. The reference image 32, however, can also contain defects, e.g., in case the reference image 32 is obtained from a different part of the same photolithography mask (die-to-die method).

Optionally, as shown in FIG. 4, the machine learning model 26 can receive a design 28 of the photolithography mask 14 as an additional input. In this way, the simulation of the second aerial image 30 from the first aerial image 22 may be simplified and its accuracy increased, for example, in case of ambiguous patterns in the first aerial image 22. In this case, the machine learning model 26 is trained using pairs of first aerial images 22 and corresponding designs 28 of photolithography masks 14.

The mask inspection system 24 can be configured according to a photolithography system 10, 10′ as shown in FIGS. 1 and 2 except for the wafer 20 that is replaced by a sensor of an image acquisition unit. The sensor records an aerial image of the photolithography mask. The optics of the photolithography system and the mask inspection system can differ.

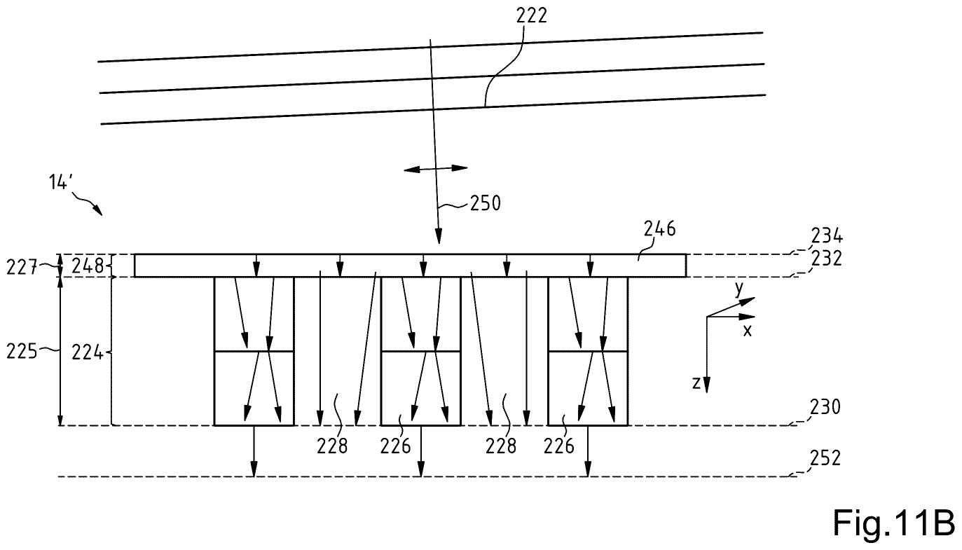

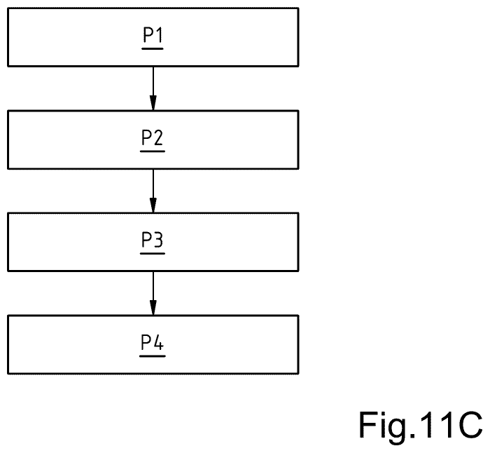

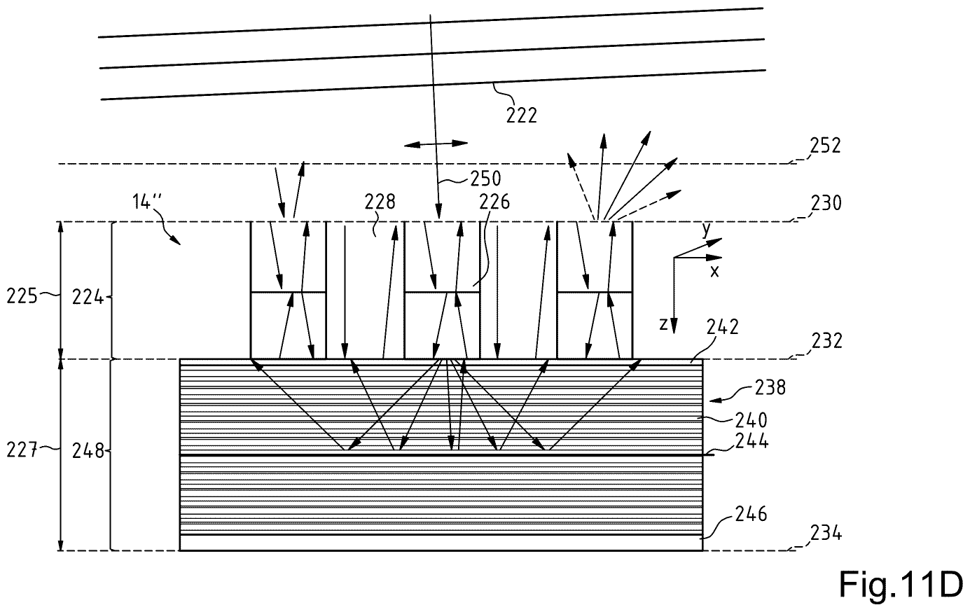

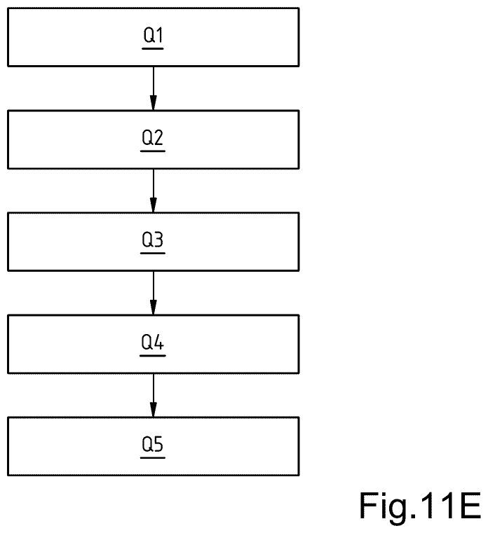

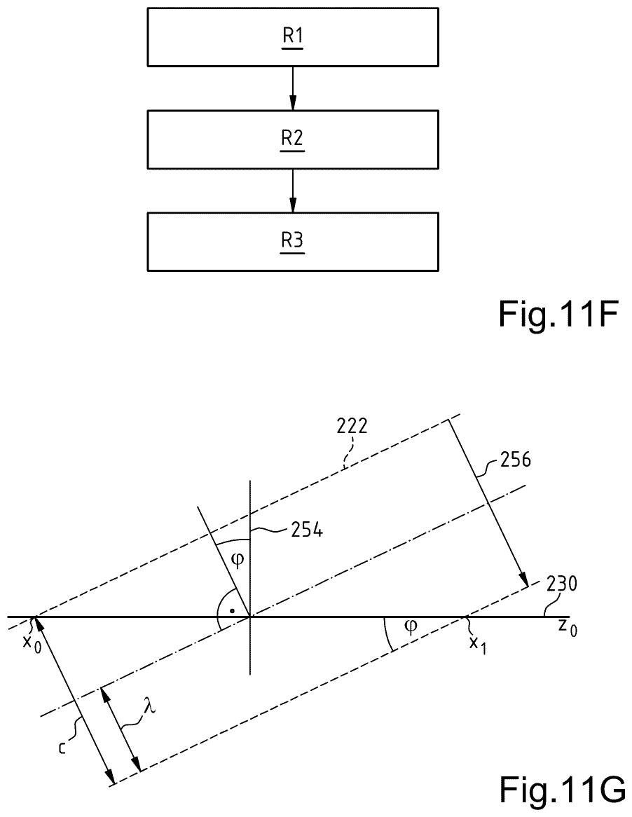

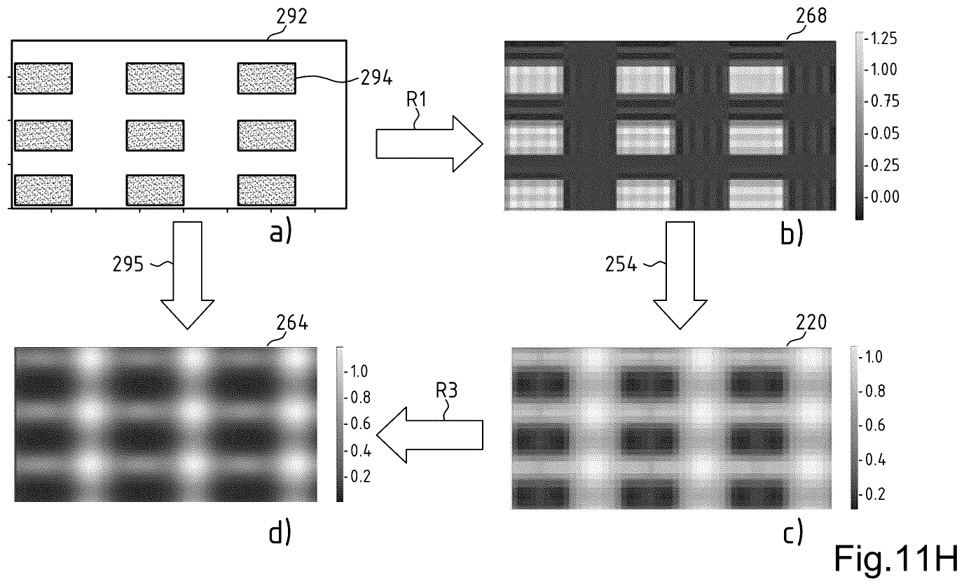

The reference image 32 is used to compare the second aerial image 30 to the reference image 32 to detect printing defects 34. It contains essentially the same mask structures as the second aerial image 30. The reference image 32 can, for example, be generated from a different portion of the second aerial image 30, in particular in case of repetitive structures. A reference image 32 could be an acquired aerial image using a different portion of the same photolithography mask, a different mask inspection system or the same mask inspection system at a different time. A reference image 32 could also refer to some model of the mask structures in the photolithography mask, e.g., a number of geometric structures describing the mask structures or the integrated circuit pattern, or to a CAD model of the photolithography mask. A reference image can also be computed from the second aerial image 30 by reconstructing the second aerial image 30 without defects or with reduced defects, e.g., using machine learning models that reconstruct a defect-free version of an aerial image. Such machine learning models can contain an encoder-decoder architecture, e.g., an autoencoder architecture. A reference image 30 could also be a simulated aerial image that is generated from the design 28 of the photolithography mask using some aerial image simulation method. Aerial image simulation methods are described below. A particularly advantageous aerial image simulation method is described with respect to FIGS. 11A to 11H.

Printing defects can be detected by comparing the second aerial image 30 to the reference image 32. To detect printing defects, for example, a machine learning model for printing defect detection that is trained to map a second aerial image 30 and a reference image 32 to printing defects 34 can be used. Such a machine learning model for printing defect detection can perform various tasks such as defect detection (presence or absence of a defect), defect localization (locating a defect), defect segmentation (computing the area, volume or outline of a defect), defect classification (assigning a defect class to a defect), defect measurement (measuring properties of the defect such as size, volume, area, dimensions, critical dimension, intensity, color, intensity distribution, color distribution, shape description parameters, frequency, number per area, location, etc.), etc. Alternatively, thresholding can be used to detect printing defects, by applying one or more thresholds or an adaptive threshold to the difference image of the second aerial image 30 and the reference image 32.

Alternatively, template-based methods can be used to detect printing defects in the second aerial image 30 or in the difference image of the second aerial image 30 and the reference image 32. Printing defects can also be determined by computing the critical dimension (CD) of mask structures in the second aerial image 30 and comparing them to the critical dimension of the corresponding mask structures in the reference image 32.

Detecting printing defects 34 can comprise detecting potential printing defects by comparing the second aerial image to the reference image, quantifying one or more properties of each potential printing defect by one or more numerical values and classifying each potential printing defect as a printing defect or non-printing defect by comparing the one or more numerical values to a printing defect specification. Quantifiable properties can, for example, comprise the size of the potential printing defect in one or more dimensions, the area or volume of the potential printing defect, the intensity or color distribution of the potential printing defect, the location of the potential printing defect, the distance of the potential printing defect to mask structures, the shape or a shape descriptor of the potential printing defect (e.g., eccentricity), the number of potential printing defects within a specific region, etc. A defect specification specifies, for example, limit values for one or more quantifiable properties, outside of which a potential printing defect is marked as a printing defect.

The method 21 for detecting printing defects 34 is particularly useful for detecting defects related to optical proximity correction methods, e.g., sub-resolution assist features, or to inverse lithography features. Both, optical proximity correction and inverse lithography aim at modifying a given design of a photolithography mask in order to reduce deviations of the printed mask pattern from the design due to the optical proximity effect caused by non-uniformity of energy intensity due to optical diffraction during the exposure process. These deviations depend on the characteristics of the patterns as well as on a variety of process conditions. Optical proximity correction is the process of correcting the layout of target patterns to be transferred onto a wafer using knowledge of the optical proximity effect.

A known OPC technique for modifying a target pattern comprising target features, i.e., features to be printed on the wafer, is to add sub-resolution assist features (SRAFs) to the target pattern. These are distinct shapes from the original design, whose dimension is intentionally chosen so as not to print at the wafer photoresist resolution, but to provide the appropriate (constructive and destructive) interference due to optical diffraction at the edges of the design shapes. SRAFs may be provided in the form of scattering bars. Since these additional features are sub-photolithographic, they will not be transferred to the wafer during printing.

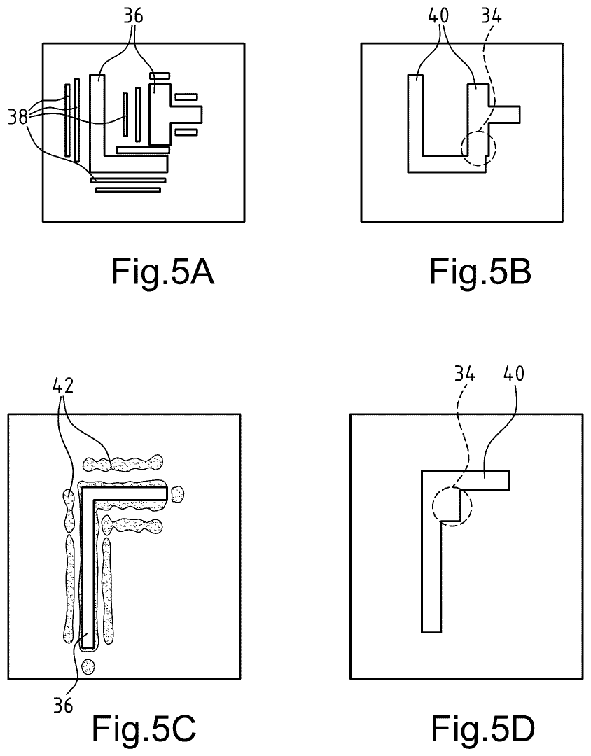

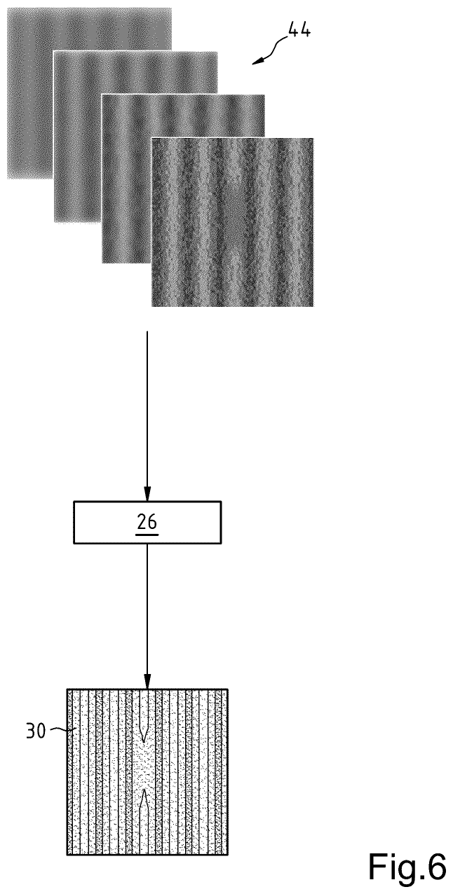

As illustrated in FIG. 5A, the placement of SRAFs 38 is commonly determined in a rule-based manner, where a set of SRAF design rules is used to generate SRAF 38 based on the layout of the target structures 36 of the target pattern in the photolithography mask 14. Yet, the rules are based on a model that cannot account for all possible 2D or 3D pattern combinations. If, for example, SRAFs are too close to target structures 36 or to each other, errors can occur on the wafer 20 as illustrated in FIG. 5B. Here, a connection between two printed structures 40 is caused by an SRAF leading to a printing defect 34. In addition, similar design configurations are not necessarily printed in a uniform way due to proximity effects.

Another technique used to improve the printability of a design onto a wafer is inverse lithography. Inverse lithography aims at solving a mathematical optimization problem that computes the optimal shape of a mask feature to be printed onto the wafer according to the design. Inverse lithography approaches generate curvilinear shapes as illustrated in FIG. 5C. FIG. 5C shows the target structures 36 and the curvilinear inverse lithography features 42 obtained by solving an optimization problem. FIG. 5D shows a printing defect 34 in a printed structure 40 caused by the inverse lithography features 42 when printing onto the wafer 20.

The placement of SRAFs 38 or inverse lithography features 42 can, thus, lead to printing defects 34 in the wafer 20. For example, there are printing defects 34 due to the actual printing of SRAFs 38 or inverse lithography features 42 on the wafer. Furthermore, adjacent structures can be bridged due to an incorrect placement of SRAFs 38 or inverse lithography features 42. Also, printed island-like SRAFs 38 or inverse lithography features 42, which are not dissolved during etching, can lift off during chemical mechanical planarization (CMP) and deposit on critical areas of the wafer, short-circuiting and damaging the circuitry.

Such SRAF or inverse lithography feature related printing defects in wafers are very hard to detect. On the one hand, the CAD model of the photolithography mask contains SRAFs 38 and/or inverse lithography features 42, which look correct. On the other hand, the printed wafer contains printing defects which often look like regular structures. Thus, SRAF or inverse lithography feature related printing defects are neither obvious from an analysis of the CAD model of the photolithography mask nor are they obvious from an analysis of the printed wafer. Therefore, the method 21 for detecting printing defects 34 is beneficial for also detecting SRAF or inverse lithography feature related printing defects that are visible on the wafer but not necessarily in the design 28 of the photolithography mask 14.

FIG. 6 illustrates the use of a focus stack 44 of aerial images as input to the machine learning model 26. The first aerial image 22 can comprise such a focus stack 44 of aerial images acquired of the same portion of the photolithography mask using different focus levels in the mask inspection system 24. As different focus levels contain different information, the accuracy of the generated second aerial image 30 is improved in this way. The machine learning model 26, in this case, is trained using a focus stack 44 of aerial images as input and generates a second aerial image as output. Alternatively, the machine learning model can be trained to map the focus stack 44 of n aerial images to a focus stack of m second aerial images. In case n=m, each aerial image of the focus stack 44 is mapped to a separate second aerial image. Printing defects can then be detected using the stack of second aerial images and the reference image 32. For example, a portion of the reference image 32 can be compared to the same portion of the second aerial image that has the best focus within this portion. In case n=1, a single aerial image is mapped to a focus stack of second aerial images. A second aerial image of a suitable focus can then be selected from the stack of second aerial images.

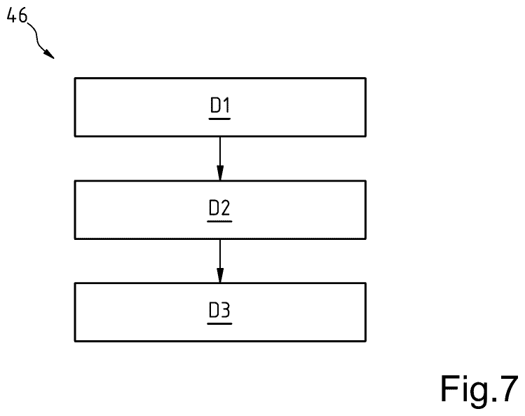

FIG. 7 shows a flow chart of a second embodiment of a method 46 for detecting printing defects in a photolithography mask that will print on a wafer when using the photolithography mask in a photolithography system to print semiconductor structures on the wafer 20. The method comprises: acquiring an aerial image of the photolithography mask using a mask inspection system in a step D1; and detecting printing defects 34 in the photolithography mask 14 by applying a machine learning model 52 to the acquired aerial image 48 and a reference image 50, wherein the acquired aerial image 48 and the reference image 50 are of the same design, and wherein the machine learning model is trained to detect printing defects 34, that will print on a wafer 20 when using the photolithography mask 14 in the specific photolithography system 10, 10′ to print semiconductor structures on the wafer 20 using the acquired aerial image 48 and the reference image 50 in a step D2. The reference image 50 is, preferably, predominantly defect-free.

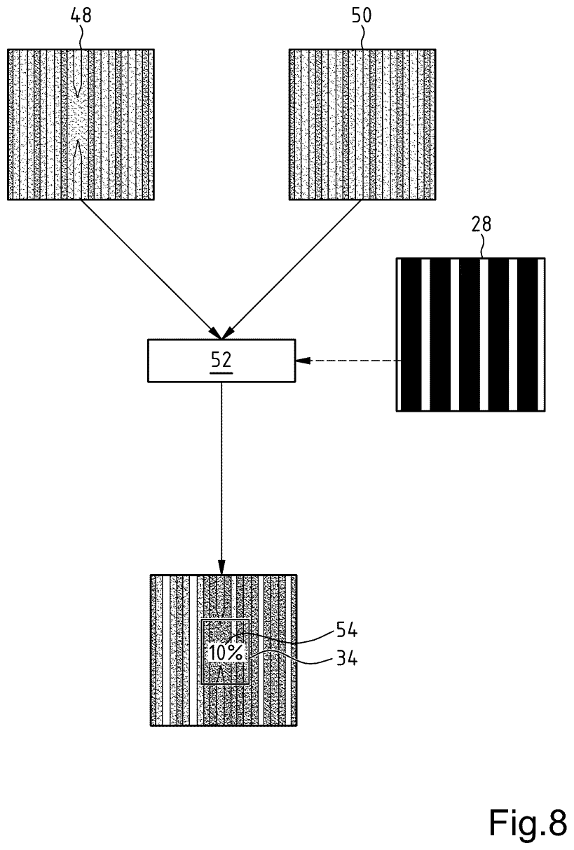

FIG. 8 illustrates the method 46 for detecting printing defects 34 according to a second embodiment of the invention. An aerial image 48 of the photolithography mask is acquired. A reference image 50 is provided. The reference image 50 is of the same design as the acquired aerial image 48 and is predominantly defect-free. The reference image 50 can be obtained as described above for the first embodiment of the method, e.g., using an aerial image of a different portion of the same photolithography mask, using an acquired, preferably predominantly defect-free aerial image, using a simulated aerial image, using an autoencoder machine learning model, etc. The acquired aerial image 48 and the reference image 50 are used as input to a machine learning model 52. The machine learning model 52 is trained to detect printing defects 34. In an example, the machine learning model 52 can be trained to distinguish between printing defects and non-printing defects.

Instead of generating a second aerial image as in the first embodiment of the invention and detecting printing defects in the second aerial image, the machine learning model in the second embodiment of the invention is trained to directly indicate printing defect detections in the aerial image acquired by the mask inspection system without the intermediate step of simulating the generation of a second aerial image of the photolithography system 10, 10′. In this way, the computation time is reduced. Furthermore, the accuracy of the detected printing defects can be improved, as the machine learning model 52 is trained end-to-end—that is using the acquired aerial image as input and directly returning printing defects—instead of requiring an additional, possibly error-prone, step for detecting printing defects 34 from the second aerial image.

The machine learning model 52 for detecting printing defects 34 can perform various tasks such as defect detection (presence or absence of a defect), defect localization (locating a defect), defect segmentation (computing the area, volume or outline of a defect), defect classification (assigning a defect class to a defect), defect measurement (measuring properties of the defect such as size, volume, area, dimensions, critical dimension, intensity, color, intensity distribution, color distribution, shape description parameters, frequency, number per area, location, etc.), etc.

In a preferred example, the machine learning model 52 further assigns one or more numerical values 54 to each printing defect detection that quantify one or more properties of the detected printing defect 34. This optional step is illustrated as step D3 in FIG. 7. The assigned numerical values 54 can be measurements of the printing defect as described in the paragraph before.

The assigned numerical values 54 can also refer to a printing defect likelihood indicated by the machine learning model 52. Such a printing defect likelihood can be directly attributed to the acquired aerial image 48 and the reference image 50 by the machine learning model 52. In particular, the one or more numerical values 54 can quantify a deviation of the mask structures of the detected printing defect 34 from corresponding mask structures in the reference image 50. For example, the one or more numerical values 54 quantify a deviation of a critical dimension of the mask structures of the detected printing defect 34 from the critical dimension of corresponding mask structures in the reference image 50. In another example, the one or more numerical values 54 quantify a deviation of a property of the mask structures of the detected printing defect 34 from the same property of the corresponding mask structures in the reference image 50. The property can refer to a size, a dimension, an area, a volume, an intensity or an average intensity, a color or an average color, a shape descriptor, a location, a brightness, a contrast, a CD uniformity (CDU), a normalized image log-slope (NILS), etc. In another example, the one or more numerical values 54 quantify the functionality of the wafer when printing the detected printing defect 34 on the wafer, e.g., the one or more numerical values 54 can indicate a likelihood that the wafer functions correctly. The one or more numerical values 54 can also indicate a classification of a potential printing defect. A classification can, for example, classify a potential printing defect as a “printing defect” that definitely prints on the wafer, as a “non-printing defect” that definitely does not print on the wafer, or as a “potential printing defect” that requires review by a user or another method or system. In this way, a pre-evaluation of the potential printing defect locations can be carried out. Only the potential printing defects requiring review need to be analyzed further, thereby saving computation time. In this way, the method can be used as a pre-processing method. Alternatively, the one or more numerical values 54 can indicate a classification of a defect type, e.g., a protrusion, an intrusion, etc.

Instead of returning printing defect detections, the machine learning model 52 can directly and only return one or more numerical values quantifying one or more properties of the printing defects 34.

For training purposes, the one or more numerical values can, for example, be derived by comparing measurements in an aerial image that emulates a photolithography system to corresponding measurements in a reference image in the training data as described below. The deviation of these measurements can be used as printing defect likelihood.

The machine learning model 52 can, optionally, receive a design 28 of the photolithography mask 14 as additional input. In this way, the accuracy of the detected printing defects 34 can be increased, for example, in case of ambiguous patterns in the acquired aerial image 48. In this case, the machine learning model 52 is trained using triplets of aerial images 48, reference images 50 and corresponding designs 28 of photolithography masks 14.

As described with respect to the first embodiment of the invention and FIGS. 5A-5D, the photolithography mask can contain sub-resolution assist features 38 and/or inverse lithography features 42. Printing defects 34 related to these features can also be successfully detected using the method according to the second embodiment of the invention.

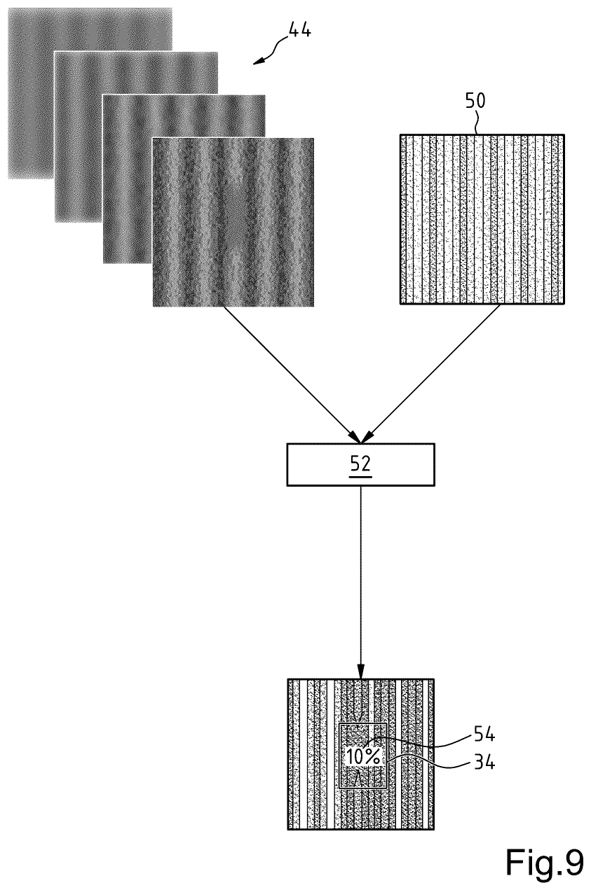

FIG. 9 illustrates the use of a focus stack of aerial images acquired of the same portion of the photolithography mask as input to the machine learning model. The acquired aerial image 48 can comprise such a focus stack 44 of aerial images acquired of the same portion of the photolithography mask using different focus levels in the mask inspection system 24. As different focus levels contain different information, the accuracy of the detected printing defects 34 and, optionally, of the one or more numerical values is improved in this way. The machine learning model 52, in this case, is trained using a focus stack 44 of acquired aerial images and a reference image 50 as input and corresponding printing defect detections 34 and, optionally, one or more numerical values 54 as output. Alternatively, a focus stack 44 of acquired aerial images and a focus stack of reference images 50 can be used as input to the machine learning model. Preferably, both focus stacks are obtained for the same focus levels. In this way, the amount of information available for the machine learning model is increased and, thus, the accuracy of the predicted printing defects as well.

The training of the machine learning model 52 used by the method for detecting printing defects 34 according to the second embodiment of the invention can be carried out as described in the following.

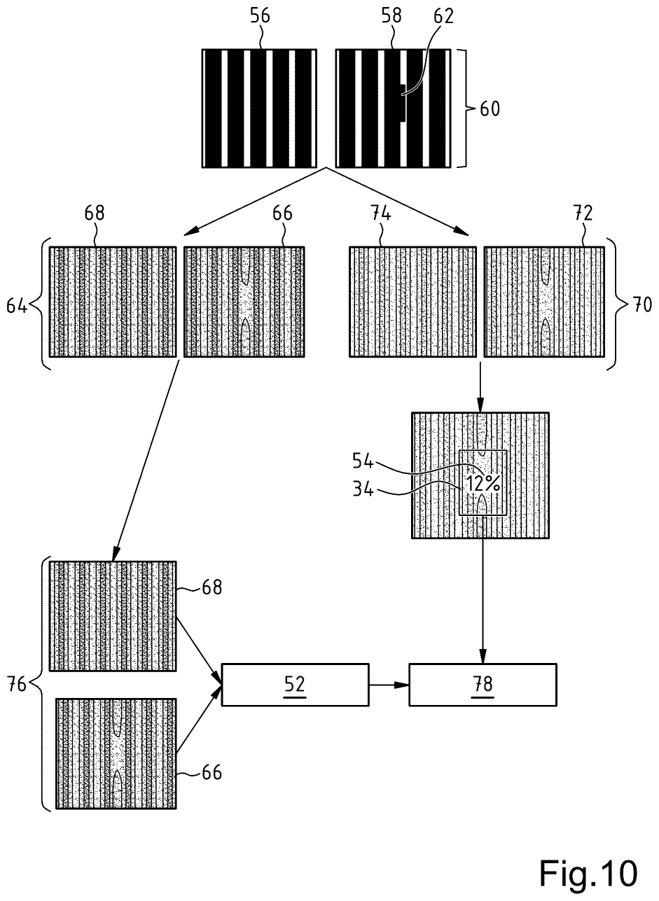

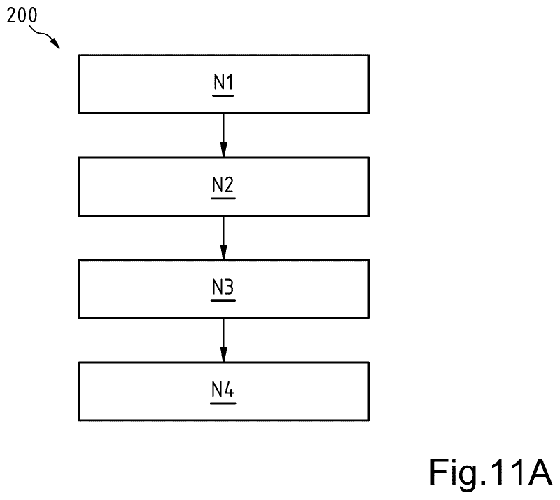

According to a third embodiment, FIG. 10 illustrates a computer implemented method for training a machine learning model 52 to detect printing defects 34 in a photolithography mask 14 that will print on a wafer 20 when using the photolithography mask 14 in a photolithography system 10, 10′ to print semiconductor structures on the wafer 20. As illustrated in FIG. 8, the machine learning model 52 maps an aerial image 48 of the photolithography mask and a reference image 50 to printing defect detections 34, wherein the reference image 50 essentially contains the same mask structures as the aerial image 48 and is, preferably, predominantly defect-free. The training method comprises: providing design pairs 60 containing designs 58 and reference designs 56 of photolithography masks 14, wherein the reference designs 56 essentially contain the same mask structures as the designs 58 and are, preferably, predominantly defect-free, and wherein at least some designs contain one or more defects 62; generating first aerial image pairs 64 containing first aerial images 66 and first reference aerial images 68 by emulating the application of a mask inspection system to photolithography masks represented by the design pairs; generating corresponding second aerial image pairs 70 containing second aerial images 72 and second reference aerial images 74 by emulating the application of the photolithography system 10, 10′ to photolithography masks 14 represented by the design pairs 60; generating corresponding printing defect detections 34 by comparing the second aerial image 72 to the second reference aerial image 74 of each second aerial image pair 70; and training the machine learning model 52 to detect printing defects 34 in a photolithography mask 14 using training data 76 comprising the generated first aerial image pairs 64 and the corresponding generated printing defect detections 34. The machine learning model 52 generates an output 78 comprising a defect detection 34. The generated printing defect detection is compared to the printing defect detection of the training data 76 in the loss function that is used during training.

It is advantageous, if the designs 58 and the first aerial images 66 contain printing defects 34 and non-printing defects in order to train the machine learning model 52 to discriminate between printing defects 34 and non-printing defects. Thus, the machine learning model 52 can be trained to mark only printing defects 34. The printing defects 34 are also visible in the second aerial images 72, whereas the non-printing defects are not visible in the second aerial images 72.

In a preferred example, the method for training the machine learning model 52 further comprises, for each printing defect detection 34, generating one or more corresponding numerical values 54 quantifying one or more properties of the printing defect detection 34 and adding the one or more numerical values 54 to the training data 76, wherein the machine learning model 52 is trained to quantify one or more properties of the printing defect detections 34 by assigning one or more numerical values 54 to the printing defect detections 34. The one or more numerical values generated as output 78 by the machine learning model 52 are compared to the corresponding one or more numerical values 54 in the training data 76 by the loss function that is used to train the machine learning model 52.

Instead of or in addition to using design pairs 60 to generate first aerial image pairs 64 and second aerial image pairs 70, the first aerial image pairs 64 and the second aerial image pairs 70 can be acquired using a mask inspection system 24 for the first aerial image pairs 64 and a photolithography system 10, 10′ for the second aerial image pairs 70. In an example, the first aerial image pairs 64 further comprise acquired aerial images of photolithography masks using the mask inspection system 24, and the second aerial image pairs 70 further comprise acquired aerial images of the same photolithography masks using the photolithography system 10, 10′.

In an example, each first aerial image 66 and each first reference aerial image 68 comprises a stack of aerial images for different focus levels of the mask inspection system 24. The stacks of first aerial images 66 and first reference aerial images 68 can be used to train a machine learning model 52 that receives a focus stack of first aerial images 66 and a focus stack of first reference aerial images 68 as input and generates one or more printing defect detections 34 and, optionally, one or more numerical values 54 quantifying one or more properties of the printing defect detections 34 as output.

The machine learning model 52 for printing defect detection can, for example, be trained using the following parameters: 50,000 first and second aerial image pairs of size 512×512, 1024×2014 or 2048×2048, a batch size of 16, AdamW optimizer, 2,000,000 training steps and a cosine annealing learning rate starting at 6e−5.

First aerial images 66, first reference aerial images 68, second aerial images 72 and/or second reference aerial images 74 used for training the machine learning model 52 for printing defect detection can, for example, be generated using an aerial image simulation method. An aerial image simulation method mathematically computes an aerial image from a design of a photolithography mask by simulating the application of an optical system, in particular a mask qualification system or a photolithography system, to a photolithography mask corresponding to the design.

An aerial image simulation method can comprise the use of a physical model for generating an aerial image from a design, or it can use machine learning models to generate an aerial image from a design. Among these methods, there are rigorous simulation methods such as finite difference time domain (FDTD) or rigorous coupled wave analysis (RCWA) that are known to a person skilled in the art. Since they require long computation times, fast approximations such as the thin element approximation (TEA) can be used. The thin element approximation (TEA) assumes that the thickness of the structures on the photolithography mask is very small compared to the wavelength, and that the widths of the structures on the photolithography mask are very large compared to the wavelength. However, as photolithographic processes use radiation of shorter and shorter wavelengths, and the structures on the patterning device become smaller and smaller and grow into the vertical dimension, these assumptions do not hold anymore, and mask 3D effects must be taken into account.

Therefore, the results of the TEA method are less accurate but much faster to obtain than rigorous simulation results.

To obtain fast and accurate results, simulation methods that are based on physical models but still do not rely on the thin mask assumption can be used.

According to an example, a not quite rigorous (NQR) aerial image simulation method can be used to simulate an aerial image of a design obtained by an optical system. This method simulates an aerial image from a design under illumination of the corresponding photolithography mask by incident electromagnetic waves with higher accuracy and at lower computation times than standard aerial image simulation methods. For simulating the interaction of electromagnetic waves with a photolithography mask the propagation of the electromagnetic waves within the different layers of the photolithography mask comprising different materials with different refractive indices has to be taken into account.

The not quite rigorous aerial image simulation method 200 for generating an aerial image of a design under illumination of a corresponding photolithography mask by incident electromagnetic waves by emulating the application of an optical system, in particular the mask inspection system or the specific photolithography system, to the photolithography mask is illustrated in FIG. 11A and comprises: a) approximately simulating the propagation of the incident electromagnetic waves within a first section of the photolithography mask that comprises multiple structures in a step N1; b) simulating the propagation of the simulated electromagnetic waves from step a) within a second section of the photolithography mask analytically or numerically in a step N2; c) simulating a representation of an electromagnetic near field of the photolithography mask by propagating the simulated electromagnetic waves from step b) to a near field plane in a step N3; and d) generating an aerial image of the photolithography mask by applying a simulation of an imaging process of the optical system to the representation of the electromagnetic near field in a step N4.

The not quite rigorous method 200 for simulating an aerial image can be applied to transmission-based photolithography masks 14′ as illustrated in FIG. 11B and reflection-based photolithography masks 14″ as illustrated in FIG. 11D.

An electromagnetic near field indicates the distribution of the electromagnetic waves 222 in a near field plane 252. The near field plane 252 can be located next to a structure plane 230 of the photolithography mask 14. Preferably, the near field plane 252 is parallel to the structure plane 230 or the base plane 234 of the photolithography mask 14. The near field plane 252 can, in general, be located anywhere between the structure plane 230 and the wafer plane 18, for example, at a distance between 0 and 1000 nm from the structure plane 230, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane 252 and the structure plane 230 are identical.

According to an embodiment, the photolithography mask 14 comprises a mask carrier 248 and a grating 224, the grating 224 comprises absorber structures 226 and non-absorber structures 228 forming a design 292 on at least a portion of the mask carrier 248. The photolithography mask 14 comprises a first section 225 extending between a structure plane 230 and a boundary plane 232 of the photolithography mask 14 and a second section 227 extending between the boundary plane 232 and a base plane 234 of the photolithography mask 14. The first section 225 comprises the grating 224, and the second section 227 comprises the mask carrier 248.

FIG. 11B illustrates the propagation of incoming electromagnetic waves 222 through a transmission-based photolithography mask 14′, e.g., a DUV photolithography mask. The photolithography mask 14′ comprises a first section 225 and a second section 227. The first section 225 contains a grating 224, and the second section 227 contains a mask carrier 248. The grating 224 is formed by a combination of absorber structures 226 and non-absorber structures 228. The absorber structures 226 are made of one or more materials which absorb electromagnetic waves 222, e.g. titanium nitride or tantalum nitride, etc. The non-absorber structures 228 are made of one or more materials which absorb electromagnetic waves 222 to a lower degree than the absorber material. For example, the non-absorber structures 228 can comprise vacuum. Thus, the grating 224 is an inhomogeneous medium. The absorber structures 226 and the non-absorber structures 228 are deposited on a mask carrier 248. The mask carrier 248 can comprise a substrate layer 246. The mask carrier 248 in the photolithography mask 14′ is delimited by a boundary plane 232 and a base plane 234 which is preferably parallel to the boundary plane 232. The boundary plane 232 is a surface plane of the mask carrier 248. The base plane 234 is a boundary plane through which the electromagnetic waves 222 enter the grating 224. The incoming electromagnetic wave 222 impinge on the base plane 234. The base plane 234 forms an interface between the mask carrier 248 and the outside of the photolithography mask 14′ through which the electromagnetic waves 222 propagate. The absorber structures 226 in the grating 224 of the photolithography mask 14′ are delimited by the boundary plane 232 and a structure plane 230. The structure plane 230 is a boundary plane which contains the portion of the surface of the absorber structures 226, which is facing away from the boundary plane 232. Preferably, the structure plane 230 is parallel to the boundary plane 232. The first section 225 of the photolithography mask 14′ extends between the structure plane 230 and the boundary plane 232 and is delimited by these planes. The second section 227 of the photolithography mask 14′ extends between the boundary plane 232 and the base plane 234 and is delimited by the boundary plane 232 and the base plane 234.

For transmission-based photolithography masks 14′, according to an example, the simulated electromagnetic waves 222 are incident on the base plane 34, propagated within the second section 227 of the photolithography mask 14′ from the base plane 234 to the boundary plane 232, and within the first section 225 of the photolithography mask 14 from the boundary plane 232 to the structure plane 230.

FIG. 11C shows a flowchart of the not quite rigorous method for simulating an aerial image in case of a transmission-based photolithography mask 14′ as shown in FIG. 11B. The simulated electromagnetic waves 222 are incident on the photolithography mask, e.g., on the base plane 234, propagated within the second section 227 of the photolithography mask, e.g., from the base plane 234 to the boundary plane 232, in a step P1, and within the first section 225 of the photolithography mask 14′, e.g., from the boundary plane 232 to the structure plane 230, in a step P2. Then a representation of the electromagnetic near field of the photolithography mask 14′ in a near field plane 252 is obtained in a step P3. Finally, an aerial image is generated from the representation of the near field by applying a simulation of an imaging process of an optical system to the representation of the electromagnetic near field in a step P4.

For reflection-based photolithography masks 14″, according to an example illustrated in FIG. 11D, the mask carrier 248 comprises a multilayer 238 in the form of a stack of optical thin films 240 for reflecting the electromagnetic waves 222, and the simulated electromagnetic waves 222 are incident on the structure plane 230, propagated within the first section 225 of the photolithography mask 14″ from the structure plane 230 to the boundary plane 232, reflected within the multilayer 238 in the second section 227 of the photolithography mask 14″ and propagated within the first section 225 of the photolithography mask 14″ from the boundary plane 232 to the structure plane 230. In this way, the not quite rigorous method 200 for simulating an aerial image can be applied to reflection-based photolithography masks 14″, e.g., EUV photolithography masks.

FIG. 11D illustrates the propagation of incoming electromagnetic waves 222 through a reflection-based photolithography mask 14″, e.g., an EUV photolithography mask. The photolithography mask 14″ comprises a first section 225 and a second section 227. The first section 225 contains a grating 224, and the second section 227 contains a mask carrier 248. The grating 224 contains absorber structures 226 and non-absorber structures 228 forming a design on at least a portion of the mask carrier 248 to be printed onto a wafer. The absorber structures 226 are made of one or more materials which absorb electromagnetic waves 222, e.g., titanium nitride or tantalum nitride, etc. The non-absorber structures 228 are made of one or more materials which absorb electromagnetic waves 222 to a lower degree than the absorber material. For example, the non-absorber structures 228 can comprise vacuum. Thus, the absorber structures 226 and the non-absorber structures 228 form an inhomogeneous medium. The absorber structures 226 and the non-absorber structures 228 are deposited on a mask carrier 248. The mask carrier 248 comprises a multilayer 238 in the form of a stack of optical thin films 240 for reflecting the electromagnetic waves 222. The mask carrier 248 can comprise a capping layer 242 and/or a substrate layer 246. The reflection of the electromagnetic waves 222 by the stack of optical thin films 240 corresponds to a reflection of the electromagnetic waves 222 at the effective mirror plane 244. The mask carrier 248 in the photolithography mask 14″ is delimited by a boundary plane 232 and a base plane 234 which is preferably parallel to the boundary plane 232. The boundary plane 232 is a surface plane of the mask carrier 248. The absorber structures 228 in the grating 224 of the photolithography mask 14″ are delimited by the boundary plane 232 and a structure plane 230. The structure plane 230 is a boundary plane which contains the portion of the surface of the absorber structures 226, which is facing away from the boundary plane 232. Preferably, the structure plane 230 is parallel to the boundary plane 232.

The structure plane 230 is a boundary plane through which the electromagnetic waves 222 enter the first section 225, e.g., the grating 224. The incoming electromagnetic waves 222 impinge on the structure plane 230. The structure plane 230 forms an interface between the photolithography mask 14″ and the outside of the photolithography mask 14″ through which the electromagnetic waves 222 propagate. The first section 225 of the photolithography mask 14″ extends between the structure plane 230 and the boundary plane 232 and is delimited by these planes. The second section 227 of the photolithography mask 14″ extends between the boundary plane 232 and the base plane 234 and is delimited by the boundary plane 232 and the base plane 234.

FIG. 11E shows a flowchart of an example of the not quite rigorous method for generating an aerial image of a design of a photolithography mask 14 in case of a reflection-based photolithography mask 14″ as shown in FIG. 11D. The mask carrier 248 comprises a multilayer 238 in the form of a stack of optical thin films 240 for reflecting the electromagnetic waves 222, and the simulated electromagnetic waves 222 are incident on the photolithography mask, e.g., on the structure plane 230, propagated within the first section 225 of the photolithography mask 14″, e.g., from the structure plane 230 to the boundary plane 232, in a step Q1, reflected within the multilayer 238 in the second section 227 of the photolithography mask 14″ in a step Q2 and propagated within the first section 225 of the photolithography mask 14″, e.g., from the boundary plane 232 to the structure plane 230, in a step Q3. Then a representation of the electromagnetic near field of the photolithography mask 14″ in a near field plane 252 is obtained in a step Q4. Finally, an aerial image is generated from the representation of the near field by applying a simulation of an imaging process of an optical system to the representation of the electromagnetic near field in a step Q5.

Instead of solving the Maxwell equations directly in the first section 225, different approximations can be used to reduce the computation time of the method. According to an example, the propagation of the incident electromagnetic waves within the first section 225 of the photolithography mask 14 in step a) is approximately simulated using a Helmholtz equation, in particular a forward Helmholtz equation.

In the photolithography setting, the following assumptions can be made: 1) the refractive index is similar for the different materials of the photolithography mask 14, e.g., the refractive index of the structures 226, in particular the absorber structures, is close to the refractive index outside the structures 226, in particular the non-absorber structures, e.g., vacuum. 2) The refractive index distribution in the first section 225 is piecewise constant without requiring a transition to be modeled. 3) The main propagation direction 250 of the incoming electromagnetic waves 222 is near vertical with respect to a main surface of the photolithography mask, in particular to the base plane 234. These assumptions allow for a simplified approximation of the propagation of the electromagnetic waves 222 within the first section 225.

Based on the time-harmonic Maxwell equations, the following equation can be derived for the electric field E of an electromagnetic wave 222:

$$Δ E ( r , ω ) + \frac{{ω}^{2}}{{c}^{2}} ϵ ( r , ω ) E ( r , ω ) = - ∇ \cdot ( \frac{∇ ϵ ( r , ω )}{ϵ ( r , ω )} \cdot E ( r , ω ) ) , \qquad ( 1 )$$

where ω is the angular frequency, c the speed of light and Γ(r, ω) the dielectric function characterizing the specific material. These relations are connected to the refractive index n(r, ω) of a material via Γ(r, ω)=n(r, ω)². The right-hand side couples the electric field components, which makes it hard to find solutions to this equation. Therefore, the right-hand side is preferably neglected. The neglection of the right-hand side remains valid if the following two assumptions are fulfilled: the considered optical system does not show a distinctive response depending upon the incident polarization, and there is no cross coupling between individual polarization components. For the lithography setting at short wavelengths, e.g., for DUV or EUV photolithography masks, there are two reasons for neglecting polarization and phononic effects, so these assumptions are valid. Firstly, the contrasts in the refractive index are low with respect to the different materials within the structures 226 and outside the structures in the first section 225. Secondly, the height a of the structures 226 is larger than the wavelength A, i.e.

$$\frac{a}{λ} \geq 2.$$

Therefore, the right-hand side of equation (1) can be neglected resulting in a Helmholtz equation

$$Δ E ( r , ω ) + \frac{{ω}^{2}}{{c}^{2}} ϵ ( r , ω ) E ( r , ω ) = 0$$

The Helmholtz equation can be simplified further. Using the following relations concerning the magnitude of the wave number |k|

$$\vert k \vert = \sqrt{{k}_{x}^{2} + {k}_{y}^{2} + {k}_{z}^{2}} = \frac{ω}{c} n ( r , ω )$$

and its connection to the wavelength λ

$$\vert k \vert = {k}_{0} n ( r , ω ) = \frac{2 π}{{λ}_{0}} n ( r , ω ) ,$$

where k₀ and λ₀ are respectively the wave vector and wavelength in vacuum, the Helmholtz equation can be rewritten as

$$Δ E ( r , ω ) + {k}_{o}^{2} {n}^{2} ( r , ω ) E ( r , ω ) = 0.$$

This equation can be rewritten using the transverse Helmholtz operator as follows:

$$( {δ}_{z}^{2} + {ℋ}_{𝒥} ) {E}_{x , y} = 0 ,$$

$$where$$

$${ℋ}_{𝒥} = {δ}_{x}^{2} + {δ}_{y}^{2} + {k}_{0}^{2} {n}^{2} ( x , y , z ) .$$

This equation can be rewritten as

$$( i \sqrt{{ℋ}_{𝒥}} + {δ}_{z} ) ( i \sqrt{{ℋ}_{𝒥}} - {δ}_{z} ) {E}_{x , y} = 0.$$

Here, the square root Helmholtz operator is introduced, being formally defined in terms of a power-series. Moreover, it is assumed that the commutator δz [symbol] can be neglected, which physically implies that back reflections within the inhomogeneous medium are ignored. Then, the forward Helmholtz equation is identified as

$${δ}_{z} {E}_{x , y} = i \sqrt{{ℋ}_{𝒥}} {E}_{x , y} .$$

The ordinary partial differential equation can be solved using multiplication with an integrating factor:

$${E}_{x , y} ( x , y , {z}_{0} + z ) = {exp}^{iz \sqrt{{ℋ}_{𝒥}}} {E}_{x , y} ( x , y , {z}_{0} ) .$$

The exponential operator can be approximated by an integral operator as shown in the appendix A of the PhD thesis “Efficient wave-optical simulations for the modeling of micro-optical elements” by Soeren Schmidt at the University of Jena. Reference is hereby made in full to the aforementioned PhD thesis, and its disclosure content is herein incorporated by reference in the description of this invention. The approximation by the integral operator yields:

$$E ( x , y , {z}_{0} + Δ z ) = \frac{1}{2 π} \int \tilde{E} ( {k}_{x} , {k}_{y} , {z}_{0} ) {e}^{{ik}_{z} ( {k}_{x} , {k}_{y} , x , y ) Δ z} {e}^{i ( {k}_{x} x + {k}_{y} y )} {dk}_{x} {dk}_{y} ,$$

$$\begin{matrix}\tilde{E} ( {k}_{x} , {k}_{y} , {z}_{0} ) = \frac{1}{2 π} \int E ( x , y , {z}_{0} ) {e}^{- i ( {k}_{x} x + {k}_{y} y )} dx dy \\ = ℱ \{ E ( x , y , {z}_{0} ) \}\end{matrix}$$

$${k}_{z} = \sqrt{{k}_{0}^{2} {n}^{2} - {k}_{x}^{2} - {k}_{y}^{2}} .$$

This approach is referred to as the angular spectrum of plane wave decomposition (ASPW) as shown in equation 1.8 of the aforementioned PhD thesis. It assumes that the electromagnetic waves are propagated within a homogeneous medium with refractive index n. However, this does not hold for the first section 225 of the photolithography mask 14 comprising structures 226 and non-structures 228.

Therefore, an extension of the ASPW to inhomogeneous media is required to describe the propagation of electromagnetic waves 222 within the first section 225 of the photolithography mask 14.

In order to account for inhomogeneous media, the propagation constant in a subsequent plane z to a given plane z₀ is computed according to the refractive index distribution as described in section 1.4 of the aforementioned PhD thesis

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2}} .$$

Therefore, according to an example, the forward Helmholtz equation can be solved using a wave propagation method. The wave propagation method is a generalization of the ASPW to inhomogeneous media and describes a wave propagation step in a plane z₀ along the z-direction perpendicular to the base plane by

$$E ( x , y , {z}_{0} + Δ z ) = \frac{1}{2 π} \int ℱ \{ E ( x , y , {z}_{0} ) \} {e}^{{ik}_{z} ( x , y , {k}_{x} , {k}_{y} ) Δ z} {e}^{i ( {k}_{x} x + {k}_{y} y )} {dk}_{x} {dk}_{y} , \qquad ( 2 )$$

where E denotes the electric field component of the electromagnetic field and (kₓ, k_{y}, k_{z})^{T} the wave vector, which locally obeys the dispersion relation

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2}} , where {k}_{0} = \frac{2 π}{{λ}_{0}} \qquad ( 3 )$$

denotes the wavenumber of light with a wavelength λ₀ in vacuum, n(x, y, z) the refractive index distribution and [symbol] the spatial Fourier Transform. The magnitude of the wave vector k is inversely proportional to the wavelength λ, and the direction of the wave vector is perpendicular to the wave front. By using this wave propagation method, the propagation of the electromagnetic waves within an inhomogeneous medium can be modeled leading to an accurate approximation of the propagation of the electromagnetic waves within the first section of the photolithography mask.

In an embodiment, the first section 225 of the photolithography mask 14 comprises structures 226 and non-structures 228 forming an inhomogeneous medium, e.g., the grating 224 comprises absorber structures and non-absorber structures. The simulation of the propagation of the electromagnetic waves 222 within the first section 225 takes into account this inhomogeneity of the material within the first section 225. At the same time, several simplifying assumptions can be exploited in the photolithography setting. In addition, the simulation of the propagation of the electromagnetic waves 222 within the second section 227 is computed analytically or numerically. In this way, an accurate and fast simulation of the propagation of the electromagnetic waves 222 within the photolithography mask 14 is obtained.

Alternatively, the forward Helmholtz equation can be solved using a beam propagation method. The beam propagation method is described, for example, in chapter 1.3 of the above-mentioned PhD thesis “Efficient wave-optical simulations for the modeling of micro-optical elements” by Soeren Schmidt.

In an example, the propagation of the incident electromagnetic waves within the first section of the photolithography mask in step a) is approximately simulated using a machine learning model. The machine learning model can, for example, comprise a neural network, e.g., a deep learning model. For example, the machine learning model can comprise a U-Net or a neural network with at least one attention mechanism, e.g., a Transformer machine learning model. The machine learning model can use a model of the photolithography mask, e.g., a design pattern, as input and map the input to an electromagnetic field as output. The machine learning model can be trained using training data obtained, e.g., from simulations described above. By using a machine learning model, the computation time can be strongly reduced, as after training a single and fast forward pass is sufficient to compute the propagation of the incident electromagnetic waves.

Due to the dependence of the dispersion relation in (3) on the spatial variables (x,y) the wave propagation method in (2) cannot be implemented using Fast Fourier Transforms (FFT). In order to use FFTs and reduce the computation time the wave propagation method in (2) can be reformulated using characteristic functions.

In an example, the first section 225 of the photolithography mask 14 is decomposed into different materials by defining a characteristic function for each material that indicates the presence of the material within different locations in the first section 225 of the photolithography mask 14, wherein at least one characteristic function is non-binary.

The first section 225 of the photolithography mask 14 can be decomposed into a finite number M of pairwise disjoint and homogeneous subregions with refractive index nm. Then, the refractive index distribution n(x, y, z₀) within a given layer z₀ can be rewritten using characteristic functions. A characteristic function

$${I}_{m}^{{z}_{0}} : X \times Y \to 𝒟$$

for a material m is a mapping from a spatial domain X×Y⊆ [symbol] × [symbol] to a value range [symbol] , which represents the presence of the material m for each location (x,y) of the spatial domain. For example,

$${I}_{m}^{{z}_{0}} ( x , y ) = \{ \begin{matrix}1 , & n ( x , y , {z}_{0} ) = {n}_{m} \\ 0 , & n ( x , y , {z}_{0} ) \neq {n}_{m}\end{matrix}$$

indicates a binary characteristic function with a value range [symbol] ={0,1}, where nₘ indicates the refractive index of material m. D can, for example, be a subset of the real numbers [symbol] ( [symbol] ⊆ [symbol] ) or of the complex numbers [symbol] ( [symbol] ⊆ [symbol] ).

FIG. 11F shows a flowchart of the not quite rigorous method for simulating an aerial image according to an example, comprising an additional characteristic function step R1 followed by simulating a representation of an electromagnetic near field in a step R2 and by applying a simulation of an imaging process of an optical system to the representation of the resulting electromagnetic near field in a step R3.

The step R1 comprises: identifying a number M of materials of the structures 226 in the first section 225 forming the design 292 of the photolithography mask 14; defining a characteristic function

$${I}_{m}^{{z}_{0}} : X \times Y \to 𝒟$$

for each material m∈{1, . . . , M}indicating the presence of the material for locations (x,y) of the photolithography mask 14 within a subset X×Y⊆ [symbol] × [symbol] of an x/y-plane at z=z₀, wherein the x/y-plane is orthogonal to the z-direction, which is perpendicular to the base plane 34; simulating the propagation of the electromagnetic waves 222 as a weighted sum over a propagation step within each of the identified materials:

$$E ( x , y , {z}_{0} + Δ z ) = {\sum }_{m = 1}^{M} {I}_{m}^{{z}_{0}} ( x , y ) {ℱ}^{- 1} \{ {e}^{{ik}_{z}^{m} ( {k}_{x} , {k}_{y} ) Δ z} ℱ \{ E ( x , y , {z}_{0} ) \} \} , \qquad ( 4 )$$

where [symbol] indicates the inverse Fourier Transform. The use of characteristic functions allows for an FFT based implementation of the wave propagation method in (2), thus saving computation time. The integrator in (4) converges linearly with the step size.

However, the discretization of the commonly used binary characteristic functions is problematic. Since binary characteristic functions are discontinuous, the Shannon-Nyquist theorem requires a very high sampling frequency (at least twice the maximum frequency of the signal) and, thus, a very high resolution of the sampling grid. In particular, if the edges of the structures 226 do not align with the sampling grid, the sampling is inaccurate. In addition, the resolution of the sampling grid depends on the size of the smallest feature. The high resolution of the sampling grid in turn leads to high computation times for generating the aerial image.

Therefore, according to an aspect of the example the characteristic functions are band-limited. A band-limited characteristic function is a characteristic function for which a finite frequency ω₀ exists such that

$$ℱ ( ω ) = 0 for \vert ω \vert > {ω}_{0} .$$

According to the Shannon-Nyquist theorem, on the one hand the required sampling frequency of the discretization of a band-limited characteristic function depends on its maximum frequency. On the other hand, a given sampling frequency of a discretization of a band-limited characteristic function directly implies its maximum frequency.

By using band-limited characteristic functions, the maximum frequency of the characteristic functions can be limited. In this way, according to the Shannon-Nyquist theorem, the required sampling frequency is reduced, so a sampling grid of lower resolution can be used for discretizing the characteristic functions (than in case of binary characteristic functions). In this way, the required computation times for generating the aerial image can be reduced. In addition, the resolution of the sampling grid is independent from the feature size of the features in the design of the photolithography mask. In contrast, for binary characteristic functions, the sampling grid resolution depends on the smallest feature of the design of the photolithography mask.

A justification of using discretized band-limited characteristic functions is given in the following: Assuming that the electromagnetic field E only contains energy at long wavelengths in the x/y-plane perpendicular to the base plane 234 of the photolithography mask 14, a linear space invariant low-pass filter P has no effect when applied to the electromagnetic field E, that is:

$$P ( E ) \approx E .$$

Equivalently, P can be written as a convolution in time domain, and the above implies:

$$\begin{matrix}P ( E ) = \int p ( {t}^{′} ) E ( t - {t}^{′} ) {dt}^{′} \\ \approx \int p ( {t}^{′} ) E ( {t}^{′} ) {dt}^{′} \\ = E ( t ) \int p ( {t}^{′} ) {dt}^{′} \\ = E\end{matrix} .$$

If the filter P is applied to the product of E with a function Θ having energy at shorter wavelengths, it follows:

$$\begin{matrix}P ( E \cdot Θ ) = \int p ( {t}^{′} ) E ( t - {t}^{′} ) Θ ( t - {t}^{′} ) {dt}^{′} \\ \approx \int p ( {t}^{′} ) E ( t ) Θ ( t - {t}^{′} ) {dt}^{′} \\ = E ( t ) \int p ( {t}^{′} ) Θ ( t - {t}^{′} ) {dt}^{′} \\ = E \cdot P ( Θ )\end{matrix} .$$

Thus, if a low pass filter is applied to the product of a slowly varying function E and a fastly varying function Θ, then the result is approximately the product of the slowly varying function E and the filtered fastly varying function P(Θ).

Applying this result to the propagator of the wave propagation method in (4)

$$P [ E ( {z}_{0} + Δ z ) ] = P ( {\sum }_{m = 1}^{M} {I}_{m}^{{z}_{0}} ( x , y ) O [ E ( {z}_{0} ) ] ) ,$$

where O denotes the linear ASPW propagator

$$O [ E ( {z}_{0} ) ] = {ℱ}^{- 1} \{ {e}^{{ik}_{z}^{m} ( {k}_{x} , {k}_{y} ) Δ z} ℱ \{ E ( {z}_{0} ) \} \} \qquad ( 5 )$$

and assuming that the electromagnetic field E(z₀) varies on a longer scale than the characteristic functions

$${I}_{m}^{{z}_{0}} ,$$

it follows:

$$P [ E ( {z}_{0} + Δ z ) ] \approx {\sum }_{m = 1}^{M} P ( {I}_{m}^{{z}_{0}} ) O [ E ( {z}_{0} ) ] .$$

Thus, the propagator for the low frequency part of the field E in the wave propagation method in (4) is obtained by applying the filter P to the characteristic functions.

By generalizing the concept of characteristic functions to non-binary characteristic functions sub-pixel design features can be resolved, and a speedup factor of about 100 can be achieved.

Apart from band-limited characteristic functions, it is also advantageous to use other non-binary characteristic functions to describe the presence of specific materials in different locations (x, y)∈X×Y of the photolithography mask 14 at z=z₀.

For example, it is advantageous to use continuous characteristic functions or complex valued characteristic functions. In this way, the material distribution within the photolithography mask can be described in a more flexible way leading to approximations of higher accuracy.

According to an aspect of the example, the value range [symbol] of at least one characteristic function comprises at least one value

$${I}_{m}^{{z}_{0}} ( x , y ) ∉ \{ 0 , 1 \} .$$

Thus, at least one characteristic function is not a binary characteristic function, since it maps to at least one non-binary value. In this way, different materials m can be present in the same location (x,y) allowing for a more flexible modeling of the refractive index distribution in the photolithography mask 14, thereby obtaining a more general description of the material distribution in the photolithography mask. By using characteristic functions having overlapping support the accuracy of the wave propagation method can be improved. The support of a real-valued function is the subset of the function domain containing the elements which are not mapped to zero. On the one hand, the presence of different materials in the same location of the photolithography mask can be used to model the distribution of materials in case that different materials are present in the same location. On the other hand, assuming the presence of different materials in the same location can be used as a mathematical means to improve the accuracy of the electromagnetic near field and aerial image even if this material distribution does not correspond to the true material distribution. In this way, more accurate electromagnetic near fields and aerial images can be computed.

According to an aspect of the example, the characteristic functions form an affine combination at each location in the first section of the photolithography mask. That means that at z=z₀:

$${\sum }_{m = 1}^{M} {I}_{m}^{{z}_{0}} ( x , y ) = 1 ∀ ( x , y ) ∈ X \times Y .$$

In particular, the characteristic functions can form a convex combination at each location of the photolithography mask at z=z₀. This constraint ensures that the amount of material present in each location of the domain of the characteristic functions is the same and amounts to 1. Thus, an accurate description of the material distribution within the photolithography mask 14 is obtained leading to an accurate approximation of the propagation of the electromagnetic waves 222 within the photolithography mask 14.

According to an aspect of the example, obtaining the characteristic functions comprises decomposing the design of the photolithography mask 14 into elements (e.g., using mathematical functions that describe the contours or area of the structures 226 such as polygons, Splines, curvilinear elements, etc.), representing the elements 294 by characteristic functions, in particular by binary characteristic functions, and applying a low pass filter to the characteristic functions. The elements 294 can, for example, be represented by characteristic functions taking on a non-zero value, for example 1, inside the element 294 and 0 outside the element 294. For example, each element 294 can be decomposed into one or more triangles, and the triangles can be represented by characteristic functions. The Fourier Transform of polygons can be obtained as described in appendix A of the PhD thesis “Photolithography Simulation” by Heinrich Kirchauer at the Technical University of Wien. Reference is hereby made in full to the aforementioned PhD thesis, and its disclosure content is herein incorporated by reference in the description of this invention. By applying a low pass filter to the characteristic functions band-limited characteristic functions 68 are obtained. Thus, the wave propagation method in (4) can be simulated using a coarse sampling grid as described above, thereby reducing the computation time.

In an example, a low pass filter is applied to the characteristic functions. In particular, applying a low pass filter to the characteristic functions can comprise applying a spatial analytical Fourier Transform to the characteristic functions followed by an inverse Fourier Transform. The analytical Fourier transform can be computed only for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a representation of the design of the photolithography mask by use of band-limited characteristic functions, which can be discretized using a sampling grid of a resolution much lower than for binary characteristic functions, thereby reducing the computation time.

According to an example, the analytical Fourier Transform used in the wave propagation method in equation (4) is approximated by a Fast Fourier Transform (FFT) and/or an analytical inverse Fourier Transform by a Fast Inverse Fourier Transform. In this way, the computation time is reduced.

The FFT implies periodic boundary conditions. However, due to the arbitrary angle of the incident electromagnetic waves, this assumption does not hold anymore. This inaccuracy is often ignored by approximation methods. Even if the design 292 is assumed to be periodic, the arbitrary illumination angle of the incident electromagnetic waves 222, e.g., with respect to the normal 254 of the structure plane 230, implies that the solution of equation (4) is only quasi periodic according to the Floquet Theorem, that means periodic with an additional phase shift α:

$$E ( x + n Δ x ) = E ( x ) {exp}^{i n α} .$$

Therefore, according to an example, the wave propagation method approximates an analytical Fourier Transform by a Fast Fourier Transform, and the wave propagation method takes into account the angle ϕ of the incident electromagnetic waves 222, e.g., the angle with respect to the normal 254 of the structure plane 230, by assuming quasiperiodic boundary conditions in the propagator step in equation (4) at one or more pairs of opposite boundaries perpendicular to a base plane 234 of the photolithography mask 14, that is in the x/y-plane. By assuming quasiperiodic boundary conditions, the accuracy of the simulated electromagnetic near field is improved.

Let E(x, y, z₀) be quasi-periodic in the x and y coordinates. Then, according to the Floquet theorem, E can be rewritten as a part E′ that is periodic in x and y multiplied with a non-periodic phase shift α=(αₓ, α_{y}) as follows:

$$E ( x , y , {z}_{0} ) = {E}^{′} ( x , y , {z}_{0} ) {exp}^{i ( {α}_{x} x + {α}_{y} y )} .$$

Then the Fourier transform of the periodic part E′ can be written as

$$= ℱ \{ {E}^{′} \} = \tilde{E} ( {k}_{x} - {α}_{x} , {k}_{y} - {α}_{y} , {z}_{0} ) .$$

It follows that

$$( {k}_{x} + {α}_{x} , {k}_{y} + {α}_{y} , {z}_{0} ) = \tilde{E} ( {k}_{x} , {k}_{y} , {z}_{0} ) .$$

Using

$$\tilde{E} ( {k}_{x} , {k}_{y} , {z}_{0} ) = ℱ \{ E ( x , y , {z}_{0} ) \} .$$

we obtain

$$\begin{matrix}E ( x , y , {z}_{0} + Δ z ) = {ℱ}^{- 1} \{ {exp}^{i {k}_{z} ( {k}_{x} , {k}_{y} ) Δ z} \tilde{E} ( {k}_{x} , {k}_{y} , {z}_{0} ) \} \\ = {ℱ}^{- 1} \{ {exp}^{i {k}_{z} ( {k}_{x} , {k}_{y} ) Δ z} ( {k}_{x} + {α}_{x} , {k}_{y} + {α}_{y} , {z}_{0} ) \} \\ = {ℱ}^{- 1} \{ {exp}^{i {k}_{z} ( {k}_{x} - {α}_{x} , {k}_{y} - {α}_{y} ) Δ z} \tilde{E} ( {k}_{x} , {k}_{y} , {z}_{0} ) \} {exp}^{i ( {α}_{x} x + {α}_{y} y )} .\end{matrix}$$

From this it can be concluded that a phase shift α in the input field that is linear in the x and y coordinates can be accommodated by reformulating the dispersion relation in equation (3) as follows:

$${k}_{z} ( x , y , {k}_{x} - {α}_{x} , {k}_{y} - {α}_{y} ) = \sqrt{{k}_{0}^{2} {n ( x , y , {z}_{0} )}^{2} - {( {k}_{x} - {α}_{x} )}^{2} - {( {k}_{y} - {α}_{y} )}^{2}} .$$

Therefore, according to an example, the dispersion relation in (3) can be reformulated using the Floquet theorem. The term within the inverse Fourier Transform is then periodic and can be computed using standard FFT.

In particular, the dispersion relation of the electromagnetic waves 222 within the first section 225 depends on the angle ϕ of the incident electromagnetic waves 222.

In particular, the dispersion relation within the first section 225 is modified by a phase shift in the coordinates parallel to the base plane 234 of the photolithography mask 14.

FIG. 11G illustrates the dependency of the phase shift vector a on the angle ϕ of the incoming electromagnetic waves 222. The angle ϕ can be measured with respect to the normal 254 of the structure plane z₀. The electromagnetic waves 222 are propagated in the direction of the wave vector 256. Let x₀ and x₁ indicate the boundaries of the unit cell in the x-direction, that is the smallest non-periodic subset of the periodic design 292. Then, using the relation

$$sin ϕ = \frac{c}{{x}_{1} - {x}_{0}}$$

the phase difference between x₀ and x₁ can be expressed in terms of ϕ as follows:

$${α}_{x} = \frac{c \cdot 2 π}{λ} = \frac{sin ϕ \cdot 2 π ( {x}_{1} - {x}_{0} )}{λ} .$$

The dependence of α_{y} on the angle of the incoming electromagnetic waves 222 can be computed analogously.

In an example, the photolithography mask 14 is a transmission-based photolithography mask.

In another example, the photolithography mask 14 is a reflection-based photolithography mask, and the second section 227 comprises a multilayer 238 in the form of a stack of optical thin films 240 for reflecting the electromagnetic waves 222.

For reflection-based photolithography masks 14, simulating the propagation of the simulated electromagnetic waves 222 from step a) within the second section 227 of the photolithography mask 14 analytically or numerically can comprise using an analytical description of the electromagnetic wave propagation within the mask carrier 248 and analytically computing the reflection of the electromagnetic waves 222 at the multilayer 238.

Therefore, according to an example, simulating the reflection of the simulated electromagnetic waves 222 from step a) within the multilayer 238 comprises the analytical computation of reflection coefficients at a boundary, e.g., at the boundary plane 232, between the second section 227 and the first section 225 of the photolithography mask 14, the reflection coefficients describing the propagation of the electromagnetic waves 222 within the stack of optical thin films 240 of the multilayer 238. The propagation within the stack of optical thin films 240 of the multilayer 238 corresponds to a reflection at an effective mirror plane 244 at a specific distance from the boundary plane 232.

In particular, the reflection coefficients at the boundary 232 can be computed separately within the structures 226 and outside the structures 226 in the first section 225 of the photolithography mask 14. For example, the reflection coefficients can be computed separately for each medium of the absorber structures and the non-absorber structures of the grating 224 at the location of the boundary plane 232. In this way, the accuracy of the generated aerial image is improved.

In an example, simulating the propagation of the simulated electromagnetic waves 222 within the second section 227 of the photolithography mask 14 comprises applying the reflection coefficients to the electromagnetic waves 222 incident on the boundary 232. In particular, simulating the reflection of the electromagnetic waves 222 within the multilayer 238 comprises replacing the phase term

$${e}^{{ik}_{z}^{m} ( {k}_{x} , {k}_{y} ) Δ z}$$

in (4) by analytical reflection coefficients rm at the boundary plane z₀:

$${E}^{up} ( x , y , {z}_{0} ) = {\sum }_{m = 1}^{M} {I}_{m}^{{z}_{0}} ( x , y ) {ℱ}^{- 1} \{ {r}_{m} ( {k}_{x} , {k}_{y} ) ℱ \{ {E}^{down} ( x , y , {z}_{0} ) \} \} ,$$

where E^{up} indicates the scalar electric field at the boundary plane z₀ directed towards the structure plane 230 of the photolithography mask 14, and E^{down} indicates the scalar electric field at the boundary plane z₀ directed towards the base plane 234 of the photolithography mask 14. In this way, the computer implemented method for generating an aerial image of a design of a photolithography mask can be applied to reflection-based photolithography masks. In addition, the accuracy of the method is improved.

As shown in the article “Optical properties of a thin-film stack illuminated by a focused field” by S. Kim, Y. Kim and I. Park, Journal of the Optical Society of America A, Vol. 17, No. 8, August 2000, equations 33 to 41, the analytical reflection coefficients rₘ for each of the N optical thin films 240 of the multilayer 238 can be computed for s-polarized waves and p-polarized waves as follows:

$${r}_{j + 1}^{s} = \frac{{Y}_{j} {a}_{11} + {Y}_{j} {Y}_{N + 1} {a}_{12} - {a}_{21} - {Y}_{N + 1} {a}_{22}}{{Y}_{j} {a}_{11} + {Y}_{j} {Y}_{N + 1} {a}_{12} + {a}_{21} + {Y}_{N + 1} {a}_{22}} ,$$

$${r}_{j + 1}^{p} = \frac{- {Y}_{j} {a}_{11} - {Y}_{j} {Y}_{N + 1} {a}_{12} + {a}_{21} + {Y}_{N + 1} {a}_{22}}{{Y}_{j} {a}_{11} + {Y}_{j} {Y}_{N + 1} {a}_{12} + {a}_{21} + {Y}_{N + 1} {a}_{22}}$$

where aᵢⱼ are the elements of the characteristic matrix A

$$A = [ \begin{matrix}{a}_{11} & {a}_{12} \\ {a}_{21} & {a}_{22}\end{matrix} ] = {A}_{j + 1} {A}_{j + 2} … {A}_{N} .$$

Here, Aⱼ₊₁ is given by

$${A}_{j + 1} = [ \begin{matrix}cos ( {k}_{0} {h}_{j + 1} ) & - \frac{i sin ( {k}_{0} {h}_{j + 1 )}}{{Y}_{j + 1}} \\ - {Y}_{j + 1} i sin ( {k}_{0} {h}_{j + 1} ) & cos ( {k}_{0} {h}_{j + 1} )\end{matrix} ] ,$$

$$where$$

$${h}_{j + 1} = {n}_{j + 1} {d}_{j + 1} cos {θ}_{j + 1}$$

$${Y}_{j + 1} = \sqrt{\frac{{ϵ}_{0}}{{μ}_{0}}} {n}_{j + 1} cos {θ}_{j + 1} for s - polarized waves$$

$${Y}_{j + 1} = \sqrt{\frac{{ϵ}_{0}}{{μ}_{0}}} \frac{{n}_{j + 1}}{cos {θ}_{j + 1}} for p - polarized waves$$

Here ∈₀ denotes the vacuum permittivity, μ₀ the vacuum magnetic permeability, nⱼ₊₁ the refractive index of the j+1-th optical thin film 240 and dⱼ₊₁ the thickness of the j+1-th optical thin film 240. Reference is hereby made in full to the aforementioned article “Optical properties of a thin-film stack illuminated by a focused field,” and its disclosure content is herein incorporated by reference in the description of this invention.

In another example, the reflection of the electromagnetic waves by the multilayer 238 could be computed numerically as follows: in a first step, the electric field at the boundary plane 232 is decomposed in its Fourier Modes. In a second step, for each Fourier mode, the reflected electromagnetic field can be computed using, for example, the transfer matrix method (described in Section 2.2 of the article “Domain Decomposition Method for Maxwell's Equations: Scattering off Periodic Structures, Achim SchAdle, Lin Zschiedrich, Sven Burger, Roland Klose, Frank Schmidt, in arXiv:math/0602179v1”). In a third step, the superposition of the reflected Fourier modes yields the reflected electromagnetic waves. Alternatively, a machine learning model can be trained for numerically simulating the propagation of the electromagnetic waves within the second section of the photolithography mask.

FIG. 11H a) to d) illustrate the steps of an example of the not quite rigorous method for simulating an aerial image. The design 292 of the photolithography mask 14 comprises elements 294 consisting of polygons in the form of rectangles shown in FIG. 11H a). In a characteristic function step R1, the elements 294 are represented by characteristic functions, e.g., by binary characteristic functions, obtained by any of the methods described above. For example, the elements 294 are represented by binary characteristic functions having the value 1 within the elements 294 and the value 0 outside. Then a spatial analytical Fourier transform is applied to the characteristic functions followed by an inverse FFT for back transformation resulting in band-limited characteristic functions 268. Here, the analytical Fourier transform is only computed for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a band-limited discretized representation of the design 292 of the photolithography mask 14, i.e., band-limited characteristic functions 268 sampled on a sampling grid of low resolution shown in FIG. 11H b). Based on the band-limited characteristic functions 268 a representation of an electromagnetic near field 220 in the form of its amplitude is shown in FIG. 11H c), which is simulated by propagating the simulated electromagnetic waves to a near field plane. Finally, an aerial image 264 shown in FIG. 11H d) is computed by applying a simulation 290 of the imaging process of the photolithography system 10, 10′ within a projection section 19 between the near field plane 252 and a wafer plane 18 to the representation of the electromagnetic near field 220. The imaging process can include resampling of the electromagnetic near field 220 to a grid of higher resolution. By computing the aerial image 264 by applying step R1 and step R3 an accurate aerial image 264 can be simulated for the design 292 of the photolithography mask 14 at low computation times due to the low resolution of the sampling grid. Thus, the computation time for obtaining the aerial image 264 is reduced compared to the simulation of an aerial image 264 by applying a rigorous simulation method (such as RCWA) to the design 292 of the photolithography mask 14 by use of rigorous simulation 295, which requires a sampling grid of high resolution.

Further details of the not quite rigorous method for simulating an aerial image are described in the international patent application PCT/EP2023/087651 and in the German patent application 102022135019.3 which are hereby incorporated by reference in their entirety.

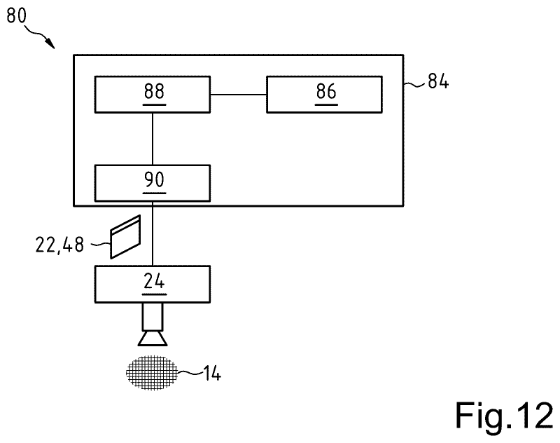

An inspection system 80 for detecting printing defects 34 in a photolithography mask 14 according to a fourth embodiment of the invention illustrated in FIG. 12 comprises: a mask inspection system 24 for acquiring an aerial image 22, 48 of the photolithography mask 14 and a data analysis device 84 comprising at least one memory 86 and at least one processor 88 configured to perform the steps of a computer implemented method 21, 46 according to any of the examples or aspects of the first or second embodiment of the invention.

The mask inspection system 24 for acquiring an aerial image 22, 48 of the photolithography mask 14 can, for example, comprise an aerial image measurement system. The mask inspection system 24 for obtaining an aerial image of the photolithography mask 14 provides the aerial image 22, 48 to the data analysis device 84. The data analysis device 84 includes a processor 88, e.g., implemented as a central processing unit (CPU) or graphics processing unit (GPU). The processor 88 can receive the aerial image 22, 48 via an interface 90. The processor 88 can load program code from a memory 86, e.g., program code for detecting printing defects 34 according to the first or second embodiment described above. The processor 88 can execute the program code.

In some implementations, a system for repairing a photolithography mask can be used to repair the printing defects in the photolithography mask after the printing defects are detected using the methods described above. The repair system can be configured to perform an electron beam-induced etching and/or deposition on the mask to repair defects detected by the data analysis device 84. The repair system can include, e.g., an electron source, which emits an electron beam that can be used to perform electron beam-induced etching or deposition on the mask. The repair system can include mechanisms for deflecting, focusing and/or adapting the electron beam. The repair system can be configured such that the electron beam is able to be incident on a defined point of incidence on the mask.

The repair system can include one or more containers for providing one or more deposition gases, which can be guided to the mask via one or more appropriate gas lines. The repair system can also include one or more containers for providing one or more etching gases, which can be provided on the mask via one or more appropriate gas lines. Further, the repair system can include one or more containers for providing one or more additive gases that can be supplied to be added to the one or more deposition gases and/or the one or more etching gases. The repair system can include a user interface to allow an operator to, e.g., operate the repair system and/or read out data. The repair system can also repair other types of objects (e.g., wafers) having integrated circuit patterns.

In some implementations, the apparatus (and its components) can include a light or electromagnetic radiation source to generate light or electromagnetic radiation, an image sensor (e.g., CCD (charged coupled device) or CMOS (complementary metal oxide semiconductor) sensor) having an array of individually addressable sensing elements for capturing images of a sample, and optics (e.g., one or more lenses, mirrors or reflecting surfaces, filters, and/or image stops) to direct and/or focus light or radiation from the one or more light or radiation source to the sample, and from the sample to the image sensor. In some implementations, the apparatus can include a data processor and a storage device. The data processor in the apparatus can be configured to process the data described herein, e.g., according to at least some steps of the methods described herein. The storage device can store at least a part of the instructions comprised in a computer program as described herein, preferably all instructions of the computer program. In some implementations, the apparatus can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The processing of data described in this document, such as detecting printing defects in a photolithography mask, and training a machine learning model to detect printing defects on a photolithography mask, can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Embodiments, examples and aspects of the invention may be described by the following clauses:
1. A method 21 for detecting printing defects 34 in a photolithography mask 14, that will print on a wafer 20 when using the photolithography mask 14 in a specific photolithography system 10, 10′ to print semiconductor structures on the wafer 20, the method comprising:
   Acquiring a first aerial image 22 of the photolithography mask 14 using a mask inspection system 24;
   Generating a second aerial image 30 of the photolithography mask 14 by applying a machine learning model 26 to the first aerial image 22, wherein the machine learning model 26 is trained to map a first aerial image 22 acquired by a mask inspection system 24 to a second aerial image 30 that emulates the application of the specific photolithography system 10, 10′ to the photolithography mask 14;
   Detecting printing defects 34 by comparing the second aerial image 30 to a reference image 32, wherein the second aerial image 30 and the reference image 32 are of the same design.
2. The method of clause 1, wherein detecting printing defects 34 comprises detecting potential printing defects by comparing the second aerial image 30 to the reference image 32, quantifying one or more properties of each potential printing defect in the second aerial image 30 by one or more numerical values and classifying one or more potential printing defects as printing defects by comparing the one or more numerical values to a printing defect specification.
3. The method of clause 1 or 2, wherein the mask inspection system 24 further generates defect candidates in the first aerial image 22, and wherein detecting printing defects 34 comprises distinguishing, among the defect candidates, between printing defects and non-printing defects by comparing the second aerial image to the reference image.
4. The method of any one of the preceding clauses, wherein the photolithography mask 14 contains sub-resolution assist features 38 and/or inverse lithography features 42.
5. The method of any one of the preceding clauses, wherein the machine learning model receives a design 28 of the photolithography mask 14 as further input.
6. The method of any one of the preceding clauses, wherein the reference image 32 is obtained by applying an autoencoder machine learning model to the second aerial image 30.
7. The method of any one of the preceding clauses, wherein the first aerial image 22 comprises a focus stack 44 of aerial images acquired of the same portion of the photolithography mask 14 using different focus levels in the mask inspection system 24.
8. A computer implemented method for training a machine learning model according to any one of the preceding clauses.
9. A method 46 for detecting printing defects 34 in a photolithography mask 14 that will print on a wafer 20 when using the photolithography mask 14 in a specific photolithography system 10, 10′ to print semiconductor structures on the wafer 20, the method comprising:
   Acquiring an aerial image 48 of the photolithography mask 14 using a mask inspection system 24;
   Detecting printing defects 34 in the photolithography mask 14 by applying a machine learning model 52 to the acquired aerial image 48 and a reference image 50, wherein the acquired aerial image 48 and the reference image 50 are of the same design, and wherein the machine learning model is trained to detect printing defects 34 using the acquired aerial image 48 and the reference image 50.
10. The method of clause 9, wherein the mask inspection system 24 further generates defect candidates in the aerial image 48, and wherein the machine learning model is trained to distinguish, among the defect candidates, between printing defects and non-printing defects by comparing the acquired aerial image to the reference image.
11. The method of clause 10, wherein the photolithography mask contains sub-resolution assist features 38 and/or inverse lithography features 42.
12. The method of clause 10 or 11, wherein the machine learning model 52 further assigns one or more numerical values to each printing defect detection that quantify one or more properties of the detected printing defect 34.
13. The method of clause 12, wherein the one or more numerical values 54 quantify a deviation of mask structures of the detected printing defect 34 from corresponding mask structures in the reference image 50.
14. The method of clause 12 or 13, wherein the one or more numerical values 54 quantify a deviation of a critical dimension of mask structures of the detected printing defect 34 from the critical dimension of corresponding mask structures in the reference image 50.
15. The method of clause 12, wherein the one or more numerical values 54 quantify one or more dimensions or a size of the detected printing defect 34.
16. The method of any one of clauses 10 to 15, wherein the machine learning model 52 receives a design 28 of the photolithography mask 14 as further input.
17. The method of any one of clauses 10 to 16, wherein the acquired aerial image 48 comprises a stack of aerial images 44 acquired of the same portion of the photolithography mask 14 using different focus levels in the mask inspection system 24.
18. A computer implemented method for training a machine learning model 52 to detect printing defects 34 on a photolithography mask, 14 that will print on a wafer 20 when using the photolithography mask 14 in a specific photolithography system 10, 10′ to print semiconductor structures on the wafer 20, wherein the machine learning model 52 maps an aerial image of the photolithography mask 14, acquired by a mask inspection system 24, and a reference image 50 to printing defect detections 34, and wherein the aerial image and the reference image 50 are of the same design, the training method comprising:
   Providing design pairs 60 containing designs 56 and reference designs 58 of photolithography masks 14, wherein the reference designs 58 contain the same mask structures as the designs 56, and wherein at least some designs 56 contain one or more defects 62;
   Generating first aerial image pairs 64 containing first aerial images 66 and first reference aerial images 68 emulating the application of a mask inspection system 24 to photolithography masks 14 represented by the design pairs 60;
   Generating corresponding second aerial image pairs 70 containing second aerial images 72 and second reference aerial images 74 by emulating the application of the photolithography system 10, 10′ to photolithography masks 14 represented by the design pairs 60;
   Generating corresponding printing defect detections 34 by comparing the second aerial image 72 to the second reference aerial image 74 of each second aerial image pair 70;
   Training the machine learning model 52 to detect printing defects 34 in a photolithography mask 14 using training data 76 comprising the generated first aerial image pairs 64 and the corresponding generated printing defect detections 34.
19. The method of clause 18, wherein the first aerial image pairs 64 further comprise acquired aerial images of photolithography masks 14 using the mask inspection system 24, and wherein the second aerial image pairs 70 further comprise acquired aerial images of the same photolithography masks 14 using a mask qualification system that emulates the specific photolithography system 10, 10′.
20. The method of clause 18 or 19, further comprising, for each printing defect detection, generating one or more numerical values 54 quantifying one or more properties of the printing defect detection and adding the one or more numerical values 54 to the training data 76, wherein the machine learning model 52 is trained to quantify one or more properties of each printing defect detection by assigning one or more numerical values 54 to the printing defect detection.
21. The method of any one of clauses 18 to 20, wherein each first aerial image and each first reference aerial image 68 comprises a stack 44 of aerial images for different focus levels of the mask inspection system 24.
22. The method of any one of clauses 18 to 21, wherein at least one aerial image, in particular a first aerial image 66, a first reference aerial image 68, a second aerial image 72 or a second reference aerial image 74, is generated from a design of the photolithography mask 14 by emulating the application of an optical system, in particular of the mask inspection system 24 or the specific photolithography system 10, 10′, to the photolithography mask 14 using the following steps:
   a) Approximately simulating the propagation of incident electromagnetic waves 222 within a first section 225 of the photolithography mask 14;
   b) Simulating the propagation of the simulated electromagnetic waves from step a within a second section 227 of the photolithography mask 14 analytically or numerically;
   c) Simulating a representation of an electromagnetic near field 220 of the photolithography mask 14 by propagating the simulated electromagnetic waves from step b to a near field plane 252; and
   d) Generating an aerial image 264 of the photolithography mask 14 by applying a simulation of an imaging process of the optical system to the representation of the electromagnetic near field 220.
23. The method of clause 22, wherein the propagation of the incident electromagnetic waves 222 within the first section 225 of the photolithography mask 14 in step a is approximately simulated using a Helmholtz equation.
24. The method of clause 23, wherein the Helmholtz equation is approximated using a forward Helmholtz equation.
25. The method of clause 24, wherein the forward Helmholtz equation is solved using a wave propagation method that approximately describes the propagation of electromagnetic waves through an inhomogeneous medium.
26. The method of any one of clauses 18 to 25, wherein the trained machine learning model 52 is used in any of the methods for detecting printing defects according to clauses 9 to 17.
27. The method of any one of clauses 9 to 17, wherein the machine learning model 52 is trained using a method according to any one of clauses 18 to 25.
28. A non-transitory computer-readable medium, comprising a stored computer program executable by a computing device, the computer program comprising code for executing a method of any one of clauses 18 to 27.
29. A computer program product comprising instructions which, when the program is executed by a computer, cause the computer to carry out a method of any one of clauses 18 to 27.
30. An inspection system 80 for detecting printing defects 34 in a photolithography mask 14, the inspection system comprising a mask inspection system 24 for acquiring an aerial image 22, 48 of the photolithography mask 14 and a data analysis device 84 comprising at least one memory 86 and at least one processor 88 configured to perform the steps of a method 21, 46 according to any one of clauses 1 to 7 or 9 to 17.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

In an aspect, the invention relates to a method for detecting printing defects 34 in a photolithography mask that will print on a wafer when using the photolithography mask in a specific photolithography system to print semiconductor structures on the wafer, the method comprising: acquiring a first aerial image 22 of the photolithography mask using a mask inspection system 24; generating a second aerial image 30 of the photolithography mask by applying a machine learning model 26 to the first aerial image 22, wherein the machine learning model 26 is trained to map a first aerial image 22 acquired by a mask inspection system 24 to a second aerial image 30 that emulates the application of the specific photolithography system to the photolithography mask; and detecting printing defects 34 in the photolithography mask by comparing the second aerial image 30 to a reference image 32.

### REFERENCE NUMBER LIST

10, 10′ Photolithography system
12 Radiation source
14 Photolithography mask
14′ Transmission-based photolithography mask
14″ Reflection-based photolithography mask
16 Illumination optics
17 Projection optics
18 Wafer plane
19 Projection section
Wafer
21 Method
22 First aerial image
24 Mask inspection system
26 Machine learning model
28 Design
Second aerial image
32 Reference image
34 Printing defect
36 Target structure
38 Sub-resolution assist feature
Printed structure
42 Inverse lithography features
44 Focus stack
46 Method
48 Acquired aerial image
50 Reference image
52 Machine learning model
54 Numerical value
56 Reference design
58 Design
60 Design pair
62 Defect
64 First aerial image pair
66 First aerial image
68 First reference aerial image
70 Second aerial image pair
72 Second aerial image
74 Second reference aerial image
76 Training data
78 Output
80 Inspection system
84 Data analysis device
86 Memory
88 Processor
90 Interface
200 Not quite rigorous aerial image generation method
220 Near field
222 Electromagnetic wave
224 Grating
225 First section
226 Structures
227 Second section
228 Non-structures
230 Structure plane
232 Boundary plane
234 Base plane
238 Multilayer
240 Optical thin film
242 Capping layer
244 Effective mirror plane
246 Substrate layer
248 Mask carrier
250 Main propagation direction
252 Near field plane
254 Normal
256 Wave vector
264 Aerial image
268 Band-limited characteristic function
292 Design
294 Elements
295 Rigorous simulation

What is claimed is:

1. A method for detecting printing defects in a photolithography mask, that will print on a wafer when using the photolithography mask in a specific photolithography system to print semiconductor structures on the wafer, the method comprising:
acquiring a first aerial image of the photolithography mask using a mask inspection system;
generating a second aerial image of the photolithography mask by applying a machine learning model to the first aerial image, wherein the machine learning model is trained to map a first aerial image acquired by a mask inspection system to a second aerial image that emulates the application of the specific photolithography system to the photolithography mask; and
detecting printing defects by comparing the second aerial image to a reference image, wherein the second aerial image and the reference image are of the same design.

2. The method of claim 1, wherein detecting printing defects comprises detecting potential printing defects by comparing the second aerial image to the reference image, quantifying one or more properties of each potential printing defect in the second aerial image by one or more numerical values and classifying one or more potential printing defects as printing defects by comparing the one or more numerical values to a printing defect specification.

3. The method of claim 1, wherein the mask inspection system further generates defect candidates in the first aerial image, and wherein detecting printing defects comprises distinguishing, among the defect candidates, between printing defects and non-printing defects by comparing the second aerial image to the reference image.

4. The method of claim 1, wherein the photolithography mask contains sub-resolution assist features and/or inverse lithography features.

5. The method of claim 1, wherein the machine learning model receives a design of the photolithography mask as further input.

6. The method of claim 1, wherein the reference image is obtained by applying an autoencoder machine learning model to the second aerial image.

7. The method of claim 1, wherein the first aerial image comprises a focus stack of aerial images acquired of the same portion of the photolithography mask using different focus levels in the mask inspection system.

8. A computer implemented method for training a machine learning model according to claim 1.

9. A method for detecting printing defects in a photolithography mask that will print on a wafer when using the photolithography mask in a specific photolithography system to print semiconductor structures on the wafer, the method comprising:
acquiring an aerial image of the photolithography mask using a mask inspection system; and
detecting printing defects in the photolithography mask by applying a machine learning model to the acquired aerial image and a reference image, wherein the acquired aerial image and the reference image are of the same design, and wherein the machine learning model is trained to detect printing defects using the acquired aerial image and the reference image.

10. The method of claim 9, wherein the mask inspection system further generates defect candidates in the aerial image, and wherein the machine learning model is trained to distinguish, among the defect candidates, between printing defects and non-printing defects by comparing the acquired aerial image to the reference image.

11. The method of claim 10, wherein the photolithography mask contains sub-resolution assist features and/or inverse lithography features.

12. The method of claim 10, wherein the machine learning model further assigns one or more numerical values to each printing defect detection that quantify one or more properties of the detected printing defect.

13. The method of claim 12, wherein the one or more numerical values quantify a deviation of mask structures of the detected printing defect from corresponding mask structures in the reference image.

14. The method of claim 12, wherein the one or more numerical values quantify a deviation of a critical dimension of mask structures of the detected printing defect from the critical dimension of corresponding mask structures in the reference image.

15. The method of claim 12, wherein the one or more numerical values quantify one or more dimensions or a size of the detected printing defect.

16. The method of claim 10, wherein the machine learning model receives a design of the photolithography mask as further input.

17. The method of claim 10, wherein the acquired aerial image comprises a stack of aerial images acquired of the same portion of the photolithography mask using different focus levels in the mask inspection system.

18. A computer implemented method for training a machine learning model to detect printing defects on a photolithography mask, that will print on a wafer when using the photolithography mask in a specific photolithography system to print semiconductor structures on the wafer, wherein the machine learning model maps an aerial image of the photolithography mask, acquired by a mask inspection system, and a reference image to printing defect detections, and wherein the aerial image and the reference image are of the same design, the training method comprising:
providing design pairs containing designs and reference designs of photolithography masks, wherein the reference designs contain the same mask structures as the designs, and wherein at least some designs contain one or more defects;
generating first aerial image pairs containing first aerial images and first reference aerial images emulating the application of a mask inspection system to photolithography masks represented by the design pairs;
generating corresponding second aerial image pairs containing second aerial images and second reference aerial images by emulating the application of the photolithography system to photolithography masks represented by the design pairs;
generating corresponding printing defect detections by comparing the second aerial image to the second reference aerial image of each second aerial image pair; and
training the machine learning model to detect printing defects in a photolithography mask using training data comprising the generated first aerial image pairs and the corresponding generated printing defect detections.

19. The method of claim 18, wherein the first aerial image pairs further comprise acquired aerial images of photolithography masks using the mask inspection system, and wherein the second aerial image pairs further comprise acquired aerial images of the same photolithography masks using a mask qualification system that emulates the specific photolithography system.

20. The method of claim 18, further comprising, for each printing defect detection, generating one or more numerical values quantifying one or more properties of the printing defect detection and adding the one or more numerical values to the training data, wherein the machine learning model is trained to quantify one or more properties of each printing defect detection by assigning one or more numerical values to the printing defect detection.

21. The method of claim 18, wherein each first aerial image and each first reference aerial image comprises a stack of aerial images for different focus levels of the mask inspection system.

22. The method of claim 18, wherein at least one aerial image, in particular a first aerial image, a first reference aerial image, a second aerial image or a second reference aerial image, is generated from a design of the photolithography mask by emulating the application of an optical system, in particular of the mask inspection system or the specific photolithography system, to the photolithography mask using the following steps:
a) approximately simulating the propagation of incident electromagnetic waves within a first section of the photolithography mask;
b) simulating the propagation of the simulated electromagnetic waves from step a) within a second section of the photolithography mask analytically or numerically;
c) simulating a representation of an electromagnetic near field of the photolithography mask by propagating the simulated electromagnetic waves from step b) to a near field plane; and
d) generating an aerial image of the photolithography mask by applying a simulation of an imaging process of the optical system to the representation of the electromagnetic near field.

23. The method of claim 22, wherein the propagation of the incident electromagnetic waves within the first section of the photolithography mask in step a) is approximately simulated using a Helmholtz equation.

24. The method of claim 23, wherein the Helmholtz equation is approximated using a forward Helmholtz equation.

25. The method of claim 24, wherein the forward Helmholtz equation is solved using a wave propagation method that approximately describes the propagation of electromagnetic waves through an inhomogeneous medium.

26. The method of claim 18, wherein the trained machine learning model is used in a second method for detecting printing defects in a photolithography mask that will print on a wafer when using the photolithography mask in a specific photolithography system to print semiconductor structures on the wafer, the second method comprising:
acquiring an aerial image of the photolithography mask using a mask inspection system; and
detecting printing defects in the photolithography mask by applying the trained machine learning model to the acquired aerial image and a reference image, wherein the acquired aerial image and the reference image are of the same design.

27. The method of claim 9, wherein the machine learning model is trained using a computer-implemented training method for training a machine learning model to detect printing defects on a photolithography mask, that will print on a wafer when using the photolithography mask in a specific photolithography system to print semiconductor structures on the wafer, wherein the machine learning model maps an aerial image of the photolithography mask, acquired by a mask inspection system, and a reference image to printing defect detections, and wherein the aerial image and the reference image are of the same design, the training method comprising:
providing design pairs containing designs and reference designs of photolithography masks, wherein the reference designs contain the same mask structures as the designs, and wherein at least some designs contain one or more defects;
generating first aerial image pairs containing first aerial images and first reference aerial images emulating the application of a mask inspection system to photolithography masks represented by the design pairs;
generating corresponding second aerial image pairs containing second aerial images and second reference aerial images by emulating the application of the photolithography system to photolithography masks represented by the design pairs;
generating corresponding printing defect detections by comparing the second aerial image to the second reference aerial image of each second aerial image pair; and
training the machine learning model to detect printing defects in a photolithography mask using training data comprising the generated first aerial image pairs and the corresponding generated printing defect detections.

28. A non-transitory computer-readable medium, comprising a stored computer program executable by a computing device, the computer program comprising code for executing a method of claim 18.

29. A computer program product comprising instructions which, when the program is executed by a computer, cause the computer to carry out a method of claim 18.

30. An inspection system for detecting printing defects in a photolithography mask, the inspection system comprising a mask inspection system for acquiring an aerial image of the photolithography mask and a data analysis device comprising at least one memory and at least one processor configured to perform the steps of a method of claim 1.
